(19) United States
(12) Patent Application Publication
(10) Pub. No.: US 2026/0202764 A1
(43) Pub. Date: Jul. 16, 2026

(54) METHODS AND SYSTEMS FOR DETERMINING RETICLE DEFORMATIONS

(71) Applicant: ASML Netherlands B.V., Veldhoven (NL)

(72) Inventors: Raaja Ganapathy SUBRAMANIAN, Maarheeze (NL); Bearrach MOEST, Eindhoven (NL); Bart Dinand PAARHUIS, Waalre (NL); Alexander Alexandrovich DANILIN, Eindhoven (NL)

(73) Assignee: ASML Netherlands B.V., Veldhoven (NL)

(21) Appl. No.: 19/135,004

(22) PCT Filed: Nov. 28, 2023
(86) PCT No.: PCT/EP2023/083407

§ 371 Date: Jun. 2, 2025

(30) Foreign Application Priority Data
Dec. 23, 2022 (EP) 22216592.0

(51) Int. Cl. G03F 7/00

(52) U.S. Cl. CPC G03F 7/70875; G03F 7/705; G03F 7/70783

(57) ABSTRACT

Disclosed herein is a computer system configured to: control a lithographic process performed on a first substrate with a reticle that is in a cold state; determine one or more performance metrics of the lithographic process in dependence on an inspection of the first substrate; determine clamping-induced deformation modes of the reticle in dependence on the one or more performance metrics; and determine and control the application of process corrections to a lithographic process performed on a second substrate in dependence on the determined clamping-induced deformation modes.

### CROSS-REFERENCE TO RELATED APPLICATION

This application claims priority of an EP application 22216592.0 which was filed on 23 Dec. 2022 and which is incorporated herein in its entirety by reference.

### FIELD

The present disclosure relates to techniques for improving the accuracy of the determination of the deformation of a reticle. Process corrections may be determined and applied in dependence on the determined deformation to reduce reticle induced errors in a lithographic process.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern of a patterning device (e.g., a mask, a reticle) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, deep ultraviolet (DUV) radiation with a wavelength of 157 nm or 193 nm or 248 nm.

A lithographic apparatus can include a reticle stage to hold a patterning device (e.g., a reticle) to transfer a pattern to a substrate. Reticle heating and/or cooling can cause changes in reticle properties that can affect the radiation beam path (e.g., focus) and cause distortions in the patterned substrate (e.g., overlay errors). Changes in reticle properties can be modeled and corrected with a reticle heating model. Known reticle heating models rely on a sensor-based approach to calibrate the reticle heating model with a reticle temperature sensor (RTS) and require a calibration lot of production wafers. In some examples, this approach can be inaccurate and inefficient since the RTS can exhibit errors, introduce unnecessary delays, and require rework of production wafers.

The shape of a reticle may also be deformed by other effects, such as the applied clamping force to the reticle. If not compensated for, all reticle shape deformations may increase distortions in the patterned substrate (e.g., overlay errors).

### SUMMARY

There is a general need to improve on known techniques for the determination of the deformation of the shape of a reticle. Process corrections may be determined and applied in dependence on the determined deformation to reduce reticle induced errors in a lithographic process. This may avoid the rework of production substrates, and/or increase the fabrication throughput and yield of lithographic processes.

According to a first aspect of the invention, there is provided a computer system configured to: control a lithographic process performed on a first substrate with a reticle that is in a cold state; determine one or more performance metrics of the lithographic process in dependence on an inspection of the first substrate; determine clamping-induced deformation modes of the reticle in dependence on the one or more performance metrics; and determine and control the application of process corrections to a lithographic process performed on a second substrate in dependence on the determined clamping-induced deformation modes.

According to a second aspect of the invention, there is provided a method comprising: performing a lithographic process on a first substrate with a reticle that is in a cold state; determining one or more performance metrics of the lithographic process in dependence on an inspection of the first substrate; determining clamping-induced deformation modes of the reticle in dependence on the one or more performance metrics; and determining and applying process corrections to a lithographic process performed on a second substrate in dependence on the determined clamping-induced deformation modes.

According to a third aspect of the invention, there is provided a system comprising: a computer system according to the first aspect; and a lithographic apparatus; wherein the computer system is configured to control the operation of lithographic apparatus.

According to a fourth aspect of the invention, there is provided a device manufacturing method using a lithographic process, the device manufacturing method comprising the method according to the second aspect.

According to a fifth aspect of the invention, there is provided a non-transitory computer readable medium program comprising computer readable instructions configured to cause a processor to control a lithographic apparatus according to the second aspect.

Implementations of any of the techniques described above may include an EUV light source, a DUV light source, a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic illustration of a lithographic apparatus, according to an exemplary aspect.

FIG. 2A is a schematic illustration of a lithographic cell, according to an exemplary aspect.

FIG. 2B is a schematic illustration of holistic lithography including a computer system to optimize a lithographic process, according to an exemplary aspect.

FIG. 3A is a schematic bottom perspective illustration of a reticle stage and a reticle, according to an exemplary aspect.

FIG. 3B is a schematic bottom plan illustration of the reticle stage shown in FIG. 3A.

FIG. 4A is a schematic top perspective illustration of a reticle exchange apparatus, according to an exemplary aspect.

FIG. 4B is a schematic partial cross-sectional illustration of the reticle exchange apparatus shown in FIG. 4A.

FIGS. 5 and 6 are schematic illustrations of reticle calibration methods, according to exemplary aspects.

FIGS. 7 and 8 are schematic illustrations of k-parameters for the reticle calibration methods shown in FIGS. 5 and 6, according to exemplary aspects.

FIGS. 9 and 10 illustrate reticle calibration diagrams, according to exemplary aspects.

FIG. 11 shows a deterministic reticle heating model.

FIG. 12 shows a deterministic reticle heating model according to a first embodiment.

FIG. 13 shows the differences in the modelled ratio of overlay to reticle temperature as lots of substrates are processed for both a known model and the model according to the first embodiment.

FIG. 14 schematically shows the overlay error that may be caused by the temperature of the reticle if processes for not correcting this source of overlay error are not performed.

FIG. 15 shows how RA measurements are obtained for processes that are performed on the first of a lot of substrates according to known techniques.

FIG. 16 shows how RA measurements are obtained for processes that are performed on a lot of substrates according to known techniques.

FIG. 17 a technique for obtaining RA measurements for processes that are performed on a lot of substrates according to a fourth embodiment.

FIG. 18 is a flowchart of a process according to a first embodiment.

FIG. 19 is a flowchart of a process according to a second embodiment.

FIG. 20 is a flowchart of a process according to a third embodiment.

FIG. 21 is a flowchart of a process according to a fourth embodiment.

FIG. 22 is a flowchart of a process according to a fifth embodiment.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to effect such feature, structure, or characteristic in connection with other aspects whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

The term “parasitic thermal effects” as used herein indicates induced or internal stresses and/or deformations of a reticle, for example, due to heating and/or cooling the reticle (e.g., by resistive heating, gas flow cooling, exposing the reticle to a dose of radiation, etc.) or mechanical pressures and/or deformations from clamping and/or holding the reticle on the reticle stage.

The term “non-production substrate” as used herein indicates a substrate (e.g., a wafer) that is not part of a production lot and is not fabricated by a lithographic process into a device (e.g., an IC chip). For example, a non-production substrate can be a chuck temperature conditioning (CTC) wafer or calibration wafer for a reticle calibration method, for example, to calibrate a reticle heating model and to acclimate the reticle by exposing the reticle and the CTC wafer to a dose of radiation and measuring a reticle alignment and/or a reticle temperature.

The term “production substrate” as used herein indicates a substrate (e.g., a wafer) that is part of a production lot and is fabricated by a lithographic process into a device (e.g., an IC chip). For example, a production substrate can be a wafer (e.g., silicon) for fabrication and inline real-time calibration of a reticle heating model, for example, by exposing the reticle and the wafer to a dose of radiation and measuring a reticle alignment and/or a reticle temperature.

The term “reticle heating model” as used herein indicates a modal deformation approach (e.g., analysis of different reticle mode shapes) to determine reticle heating effects based on reticle alignment and/or reticle shape deformations and a finite element model (FEM) (e.g., COMSOL). For example, the reticle heating model can be deterministic (e.g., no random future states) or non-deterministic (e.g., including random future states) reticle heating effects. Further, the reticle heating model can be deemed a reticle heating execution algorithm (RHEA) that uses inline modal calibrations to determine the baseline reticle heating dynamics. The reticle heating model can be calibrated by exposing a reticle and a non-production substrate to a dose of radiation for inline real-time calibration of the reticle heating model. In some aspects, for example, the reticle heating model can be calibrated by exposing a reticle and a production substrate to a dose of radiation for inline real-time calibration of the reticle heating model. Other reticle heating models utilize a sensor-based approach (e.g., using RTS measurements) to calibrate the reticle heating model. This is described in further detail in U.S. Pat. Nos. 10,429,749, 10,281,825, and U.S. Publication No. 2020/0166854, which are incorporated by reference herein in their entireties.

Reticle heating causes changes in reticle properties that can affect the radiation path and cause fabrication errors (e.g., overlay). Reticle mechanical deformations (e.g., based on reticle temperature) can be calculated and decomposed into k-parameters. Each thermo-mechanical mode (e.g., eigenvector) can be modeled in time using modal participation factor and time constant τ. Measured overlay and/or alignment can be used to model the related k-parameter drifts, which can be used to calculate adjustments to the feed-forward parameters μ and τ. The reticle heating model can also include adjusting feed-forward parameters μ and τ. This is described in further detail in U.S. Pat. No. 10,429,749, U.S. Publication No. 2020/0166854, and WIPO Publication No. 2021/043519, which are incorporated by reference herein in their entireties.

The term “finite element model” or “FEM” as used herein indicates a method for numerically solving differential equations arising in the reticle heating model (e.g., heat transfer equations, structural analysis equations, fluid flow equations, etc.). For example, baseline reticle heating dynamics can be analyzed with the FEM through finite element analysis. This is described in further detail in U.S. Pat. Nos. 10,429,749, 10,281,825, and U.S. Publication No. 2020/0166854, which are incorporated by reference herein in their entireties.

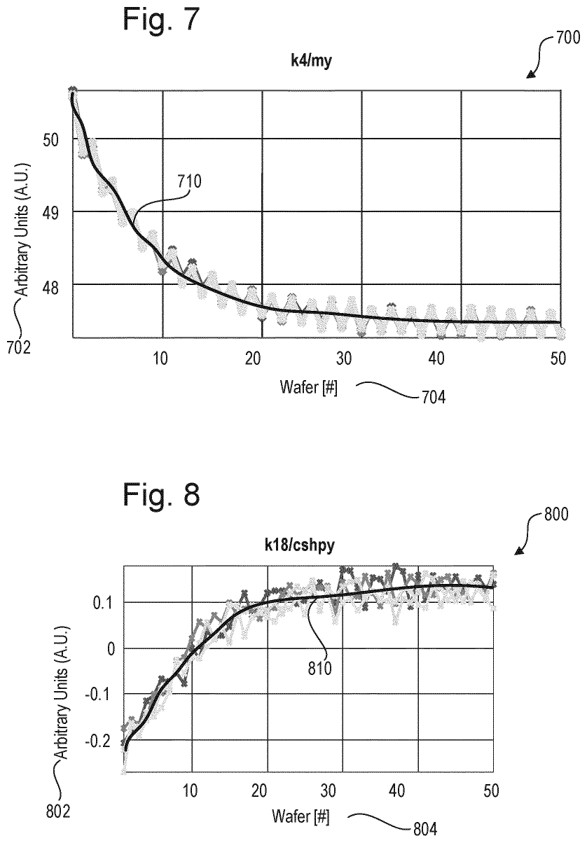

The term “key performance indicators” or “KPIs” or “k-parameters” as used herein indicates coefficients of polynomials that are fit to distortions of reticle alignment marks and/or edge alignment marks. The k-parameters parameterize the distortion of the imaging across the field of each substrate. For example, each k-parameter can describe a certain image distortion component (e.g., scaling error, barrel distortion, pincushion distortion, etc.). For example, two important k-parameters are k4 (e.g., k4/my shown in FIG. 7) that represents distortion in Y-axis magnification and k18 (e.g., k18/cshpy shown in FIG. 8) that represents distortion in Y-axis barrel shape. The k-parameters can be used as input to a lithographic process (e.g., lithographic apparatus LA, lithographic cell LC, control system CL) to correct the distortion. This is described in further detail in U.S. Pat. No. 10,429,749, U.S. Publication No. 2020/0166854, and WIPO Publication No. 2021/043519, which are incorporated by reference herein in their entireties.

The term “inline real-time calibration” as used herein indicates calibration of the reticle heating model during actual fabrication of production substrates. For example, a calibration lot of production substrates can be avoided and rework of production substrates for calibration purposes can be reduced or avoided. The calibration can be done inline by exposing a reticle and a production substrate to a dose of radiation. Further, the calibration can be done in real-time (e.g., at a real-time frame rate or a computing rate of 2.56 seconds or less).

Aspects of the disclosure may be implemented in hardware, firmware, software, or any combination thereof. Aspects of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Before describing such aspects in more detail, however, it is instructive to present example environments in which aspects of the present disclosure may be implemented.

### Exemplary Lithographic System

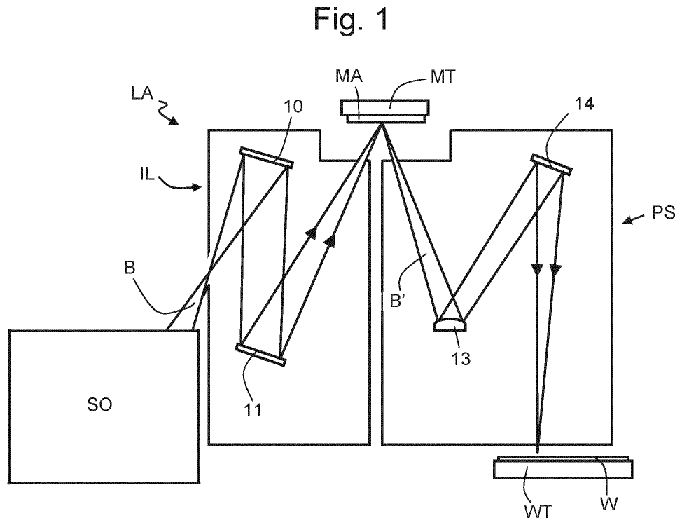

FIG. 1 shows a lithographic system comprising a radiation source SO and a lithographic apparatus LA. The radiation source SO is configured to generate an EUV and/or a DUV radiation beam B and to supply the EUV and/or DUV radiation beam B to the lithographic apparatus LA. The lithographic apparatus LA comprises an illumination system IL, a support structure MT (e.g., a mask table, a reticle table, a reticle stage) configured to support a patterning device MA (e.g., a mask, a reticle), a projection system PS, and a substrate table WT configured to support a substrate W.

The illumination system IL is configured to condition the EUV and/or DUV radiation beam B before the EUV and/or DUV radiation beam B is incident upon the patterning device MA. Thereto, the illumination system IL may include a faceted field mirror device 10 and a faceted pupil mirror device 11. The faceted field mirror device 10 and faceted pupil mirror device 11 together provide the EUV and/or DUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV and/or DUV radiation beam B interacts with the patterning device MA. This interaction may be reflective (as shown), which may be preferred for EUV radiation. This interaction may be transmissive, which may be preferred for DUV radiation. As a result of this interaction, a patterned EUV and/or DUV radiation beam B′ is generated. The projection system PS is configured to project the patterned EUV and/or DUV radiation beam B′ onto the substrate W. For that purpose, the projection system PS may comprise a plurality of mirrors 13, 14 which are configured to project the patterned EUV and/or DUV radiation beam B′ onto the substrate W held by the substrate table WT. The projection system PS may apply a reduction factor to the patterned EUV and/or DUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV and/or DUV radiation beam B′, with a pattern previously formed on the substrate W.

### Exemplary Lithographic Cell

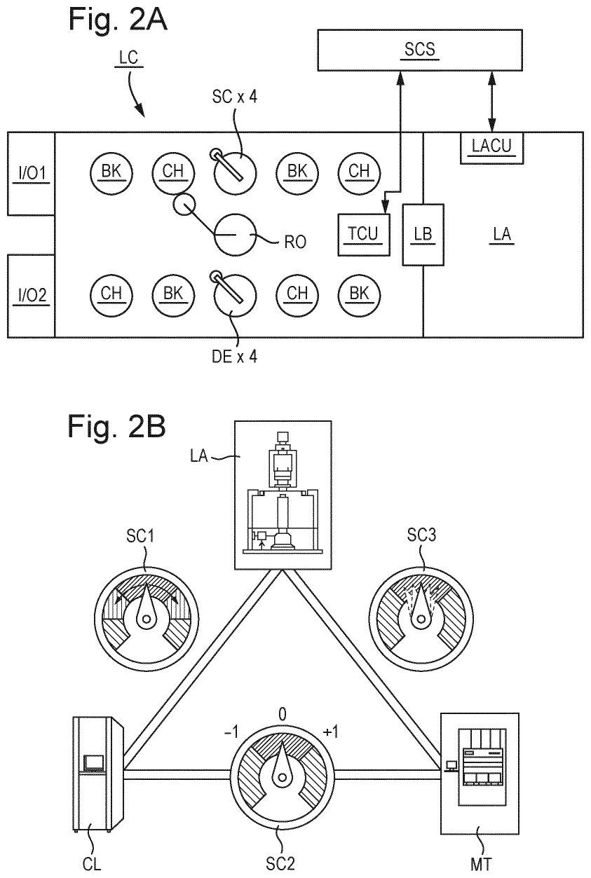

FIG. 2A shows a lithographic cell LC, also sometimes referred to as a lithocell or cluster. Lithographic apparatus LA may form part of lithographic cell LC. Lithographic cell LC may also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus LA. These devices, which are often collectively referred to as the track, are under the control of a track control unit TCU which is itself controlled by a supervisory control system SCS, which also controls the lithographic apparatus LA via lithography control unit LACU. Thus, the different apparatuses can be operated to maximize throughput and processing efficiency.

In order for the substrates W exposed by the lithographic apparatus LA to be exposed correctly and consistently, it is desirable to inspect substrates to measure properties of patterned substrates, for example, overlay errors between subsequent layers, line thicknesses, critical dimensions (CD), etc. For this purpose, inspection tools (e.g., metrology tool MT) may be included in lithographic cell LC and/or lithographic apparatus LA. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus or metrology tool MT, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of lithographic cell LC, integrated into lithographic apparatus LA, and/or be a stand-alone device. The inspection apparatus may measure the properties on a latent image (e.g., image in a resist layer after the exposure), on a semi-latent image (e.g., image in a resist layer after a post-exposure bake step), on a developed resist image (e.g., image in which the exposed or unexposed parts of the resist have been removed), or on an etched image (e.g., image after a pattern transfer step, such as etching).

### Exemplary Computer System

FIG. 2B shows a computer system CL, also referred to as a controller or processor. Computer system CL may be part of lithographic cell LC, integrated into lithographic apparatus LA, and/or be a stand-alone device. Computer system CL is configured to optimize a lithographic process, for example, calibrate a reticle heating model. Typically the patterning process in lithographic apparatus LA is one of the most critical steps in the processing, which requires high accuracy of dimensioning and placement of structures on the substrate W. To ensure this high accuracy, three systems can be combined in a so-called “holistic” control environment as schematically depicted in FIG. 2B. As shown in FIG. 2B, the “holistic” environment can include lithographic apparatus LA, computer system CL, and metrology tool MT. For example, lithographic apparatus LA (a first system) can be connected to computer system CL (a second system) and metrology tool MT (a third system).

The key of such holistic lithography is to optimize the cooperation between these three systems to optimize a lithographic process, for example, to enhance the overall process window and provide tight controls loops to ensure that the patterning performed by lithographic apparatus LA stays within a process window. The process window defines a range of process parameters, for example, dose, focus, overlay, etc., within which a specific manufacturing process yields a defined result, for example, a functional semiconductor device—typically within which the process parameters in the lithographic process or patterning process are allowed to vary.

Computer system CL may, for example, use (e.g., part of) the design layout to be patterned to predict which resolution enhancement techniques to use and to perform computational lithography simulations and calculations, for example, to determine which mask layout and lithographic apparatus settings achieve the largest overall process window of the patterning process (shown in FIG. 2B by the double arrow in the first scale SC1). Typically, the resolution enhancement techniques are arranged to match the patterning possibilities of lithographic apparatus LA. Computer system CL may also be used to detect where within the process window lithographic apparatus LA is currently operating (e.g., using input from metrology tool MT) to predict whether defects may be present, for example, due to sub-optimal processing (shown in FIG. 2B by the arrow pointing “0” in the second scale SC2).

Metrology tool MT may provide input to computer system CL, for example, to enable accurate simulations and predictions. For example, metrology tool MT may provide alignment information. Metrology tool MT may provide feedback (e.g., via computer system CL) to lithographic apparatus LA to identify possible drifts, for example, in a calibration status of lithographic apparatus LA (shown in FIG. 2B by the multiple arrows in the third scale SC3). In lithographic processes, it is desirable to make frequent measurements of the structures created, for example, for process control and verification. Different types of metrology tools MT can be used, for example, to measure one or more properties relating to lithographic apparatus LA, a substrate W to be patterned, and/or reticle alignment. This is described in further details in U.S. Pat. No. 11,099,319 and WIPO Publication No. 2021/043519, which are incorporated by reference herein in their entireties.

### Exemplary Reticle Stage and Reticle

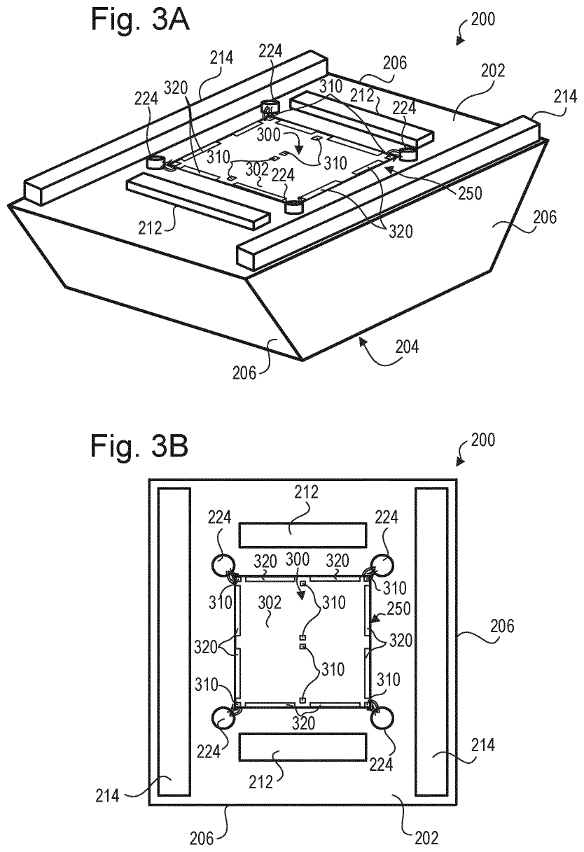

FIGS. 3A and 3B show schematic illustrations of reticle stage 200, according to exemplary aspects. FIG. 3A is a schematic bottom perspective illustration of reticle stage 200 and reticle 300, according to an example aspect. FIG. 3B is a schematic bottom plan illustration of reticle stage 200 and reticle 300 shown in FIG. 3A.

Reticle stage 200 (e.g., support structure MT) can be used in a lithographic apparatus (e.g., lithographic apparatus LA) to hold a patterning device (e.g., patterning device MA). Reticle stage 200 can include bottom stage surface 202, top stage surface 204, side stage surfaces 206, clamp 250, reticle cage 224, and/or reticle 300. In some aspects, reticle stage 200 with reticle 300 can be implemented in lithographic apparatus LA. For example, reticle stage 200 can be support structure MT in lithographic apparatus LA. In some aspects, reticle 300 can be disposed on bottom stage surface 202 and held by clamp 250. For example, as shown in FIGS. 3A and 3B, reticle 300 can be disposed on clamp 250 (e.g., an electrostatic clamp) at a center of bottom stage surface 202 with reticle frontside 302 facing perpendicularly away from bottom stage surface 202. In some aspects, reticle cage 224 can be disposed on bottom stage surface 202. For example, as shown in FIGS. 3A and 3B, reticle 300 can be disposed at a center of bottom stage surface 202 and secured by reticle cages 224 adjacent to each corner of reticle 300.

In some lithographic apparatuses, for example, lithographic apparatus LA, reticle stage 200 with clamp 250 can be used to hold and position reticle 300 for scanning or patterning operations. In some aspects, as shown in FIGS. 3A and 3B, reticle stage 200 can include first encoder 212 and second encoder 214 for positioning operations. For example, first and second encoders 212, 214 can be interferometers. First encoder 212 can be attached along a first direction, for example, a transverse direction (i.e., X-direction) of reticle stage 200. And second encoder 214 can be attached along a second direction, for example, a longitudinal direction (i.e., Y-direction) of reticle stage 200.

As shown in FIGS. 3A and 3B, reticle 300 can include reticle frontside 302, alignment mark 310, and/or edge alignment mark 320. Alignment mark 310 is configured to measure a reticle alignment between reticle 300 and a substrate (e.g., substrate W, non-production substrate, production substrate). In some aspects, as shown in FIGS. 3A and 3B, one or more alignment marks 310 can be disposed in the corners and/or the center of reticle 300 for an RA measurement. Edge alignment mark 320 is configured to measure a reticle shape deformation of reticle 300 due to thermal expansion when reticle 300 is not within a predetermined temperature (e.g., at 22° C.±0.2° C.). In some aspects, as shown in FIGS. 3A and 3B, one or more edge alignment marks 320 can be disposed along the perimeter edges (e.g., horizontal and vertical edges) of reticle 300 for a reticle shape deformation (RSD) measurement. In some aspects, the results of the RA measurement and/or the RSD measurement can be converted to a reticle temperature, for example, by a FEM that solves for temperature based on reticle alignment and/or reticle deformation.

### Exemplary Reticle Exchange Apparatus

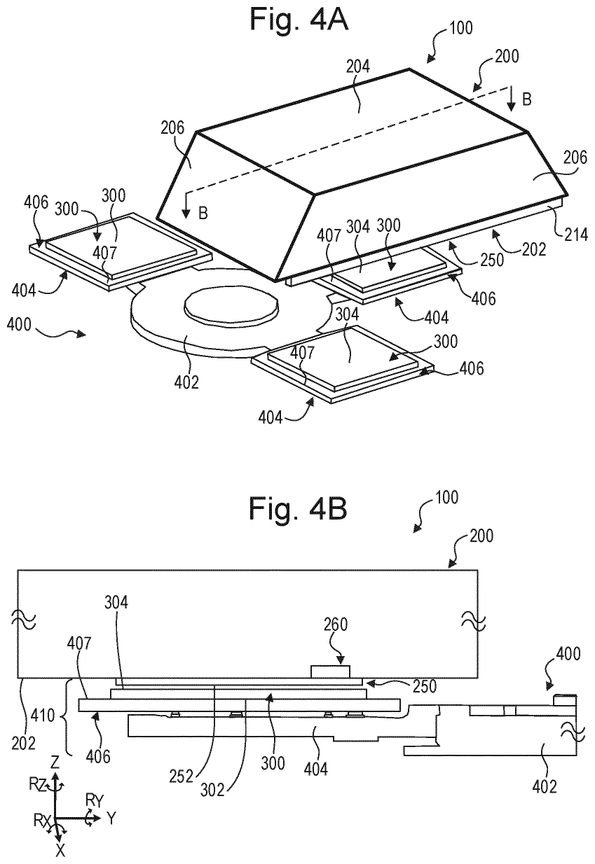

FIGS. 4A and 4B show schematic illustrations of reticle exchange apparatus 100, according to exemplary aspects. FIG. 4A is a schematic top perspective illustration of reticle exchange apparatus 100, according to an exemplary aspect. FIG. 4B is a schematic partial cross-sectional illustration of reticle exchange apparatus 100 shown in FIG. 4A.

Reticle exchange apparatus 100 can be configured to reduce reticle exchange time and thermal stresses in reticle 300 to increase overall throughput, for example, in lithographic apparatus LA. In some aspects, reticle exchange apparatus 100 can reduce stress in reticle 300 by removing reticle 300 from reticle stage 200 to in-vacuum robot (IVR) 400. For example, reticle exchange apparatus 100 can quickly unclamp reticle 300 from reticle cages 224 and clamp 250 and transfer reticle 300 to IVR 400 to release thermal stress in reticle 300. In some aspects, reticle exchange apparatus 100 can reduce stress in reticle 300 and increase throughput by unclamping and transferring reticle 300 from reticle stage 200 to IVR 400 and quickly returning and clamping reticle 300 back to reticle stage 200. As shown in FIGS. 4A and 4B, reticle exchange apparatus 100 can include reticle stage 200, clamp 250, and IVR 400.

IVR 400 can include reticle handler 402 with one or more reticle handler arms 404. In some aspects, reticle handler 402 can be a rapid exchange device (RED), which is configured to efficiently rotate and minimize reticle exchange time. Reticle handler arm 404 can include reticle baseplate 406 configured to hold an object, for example, reticle 300. In some aspects, reticle baseplate 406 can be an extreme ultraviolet inner pod (EIP) for reticle 300. Reticle baseplate 406 includes reticle baseplate frontside 407, and reticle 300 includes reticle backside 304.

As shown in FIGS. 4A and 4B, reticle baseplate 406 can hold reticle 300 such that reticle baseplate frontside 407 and reticle backside 304 each face bottom stage surface 202 and clamp frontside 252. For example, reticle baseplate frontside 407 and reticle backside 304 can be facing perpendicularly away from bottom stage surface 202 and clamp frontside 252. As shown in FIG. 4B, reticle exchange apparatus 100 can include reticle exchange area 410, which is the cross-sectional area between clamp 250, reticle 300, reticle baseplate 406, and reticle handler arm 404 during a reticle exchange process.

In one example, during a reticle exchange process, reticle handler arm 404 of reticle handler 402 positions reticle 300 on reticle baseplate 406 towards clamp 250 in reticle exchange area 410. As described above, a reticle handoff from reticle handler 402 to clamp 250 and vice-versa can release thermal stress in reticle 300 and reduce parasitic thermal effects in reticle 300.

### Exemplary Reticle Calibration Methods

As discussed above, a lithographic apparatus (e.g., lithographic apparatus LA) can include a reticle stage (e.g., support structure MT, reticle stage 200) to hold a patterning device (e.g., patterning device MA, reticle 300) to transfer a pattern to a substrate (e.g., substrate W). Reticle heating and/or cooling can cause changes in reticle properties that can affect the radiation beam path (e.g., focus) and cause distortions in the patterned substrate (e.g., overlay errors). Changes in reticle properties can be modeled and corrected with a reticle heating model. Current reticle heating models rely on a sensor-based application specific approach to calibrate the reticle heating model with an RTS and require a calibration lot of production wafers.

In some examples, this approach can be inaccurate and inefficient since the RTS can exhibit errors, can introduce unnecessary delays, and can require rework of production wafers. In some aspects, the RTS has a temperature gradient variation of about ±0.6° C., which can cause an overlay mismatch of about 1 nm/° C. Also, in some aspects each reticle temperature measurement with the RTS takes about five seconds per wafer, which can introduce additional delays. In addition, in some aspects, pre-conditioning of the reticle in an internal reticle library (IRL) can take additional time to condition (e.g., cool) the reticle to a desired temperature (e.g., 22° C.±0.2° C.) and some reticles can be kept in the IRL for longer than needed. For example, a delay of up to seven minutes can occur each time due to pre-conditioning delays, which can translate to a production loss of up to thirty-five production wafers per occurrence. Further, variations in a reticle's thermo-mechanical properties prior to calibration can amplify and exacerbate an overlay mismatch (e.g., increase from 1 nm/° C. to over 2.1 nm/° C.). In addition, production wafers used for calibration may be reworked over time, which can introduce additional delays and reduce overall throughput.

Aspects of reticle calibration apparatuses, systems, and methods as discussed below can increase calibration accuracy and speed of a reticle heating model, reduce conditioning times of a reticle, reduce stress in the reticle, avoid rework of production substrates, and/or increase fabrication throughput and yield of a lithographic process.

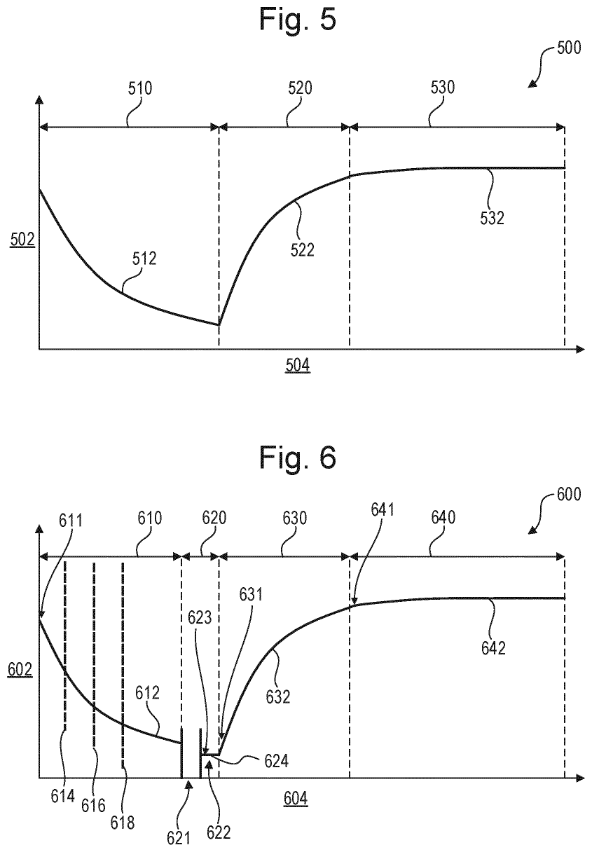

FIGS. 5-8 illustrate reticle calibration methods 500, 600, according to various exemplary aspects. FIG. 5 is a schematic illustration of reticle calibration method 500, according to an exemplary aspect. FIG. 6 is a schematic illustration of reticle calibration method 600, according to an exemplary aspect. FIG. 7 is schematic illustration of k4-parameter 700 for reticle calibration method 600 shown in FIG. 6, according to an exemplary aspect. FIG. 8 is schematic illustration of k18-parameter 800 for reticle calibration method 600 shown in FIG. 6, according to an exemplary aspect.

FIG. 5 illustrates reticle calibration method 500, according to an exemplary aspect. Reticle calibration method 500 can be configured to reduce effects of heating and/or cooling reticle 300 in a lithographic process. Reticle calibration method 500 can be further configured to increase calibration accuracy and speed of a reticle heating model and increase fabrication throughput and yield of the lithographic process. Although reticle calibration method 500 is shown in FIG. 5 as a stand-alone method and/or system, the aspects of this disclosure can be used with other apparatuses, systems, and/or methods, such as, but not limited to, lithographic apparatus LA, lithographic cell LC, computer system CL, metrology tool MT, support structure MT, patterning device MA, reticle exchange apparatus 100, reticle stage 200, reticle 300, IVR 400, and/or reticle calibration method 600.

As shown in FIG. 5, reticle calibration method 500 can include reticle temperature 502, process flow 504, conditioning phase 510, calibrating phase 520, and/or processing phase 530. Conditioning phase 510 can be configured to adjust an initial temperature of reticle 300 to a predetermined temperature. In one aspect, the initial temperature of reticle 300 can be in a range of about 20° C. to about 24° C., depending on where reticle 300 comes from in the lithography system (e.g., IRL, outside metrology tool MT, reticle stage 200, integrated reticle inspection system (IRIS), etc.). For example, reticle 300 can initially be in a “hot” state (e.g., reticle temperature greater than 22° C.±0.2° C.), a “cold” state (e.g., reticle temperature less than 22° C.±0.2° C.), and a “perfectly-conditioned” state (e.g., reticle temperature is 22° C.±0.2° C.). In one aspect, conditioning phase 510 cools and/or heats reticle 300 to the predetermined temperature (e.g., 22° C.±0.2° C.), as shown by conditioning reticle temperature 512.

In some aspects, reticle 300 can be conditioned (e.g., heated and/or cooled) by the IRL. For example, reticle 300 can be placed in the IRL for about forty minutes to reach the predetermined temperature (e.g., 22° C.±0.2° C.). In some aspects, reticle 300 can be conditioned (e.g., heated and/or cooled) by a conditioning slot that rapidly heats and/or cools reticle 300 to the predetermined temperature (e.g., 22° C.±0.2° C.). For example, the conditioning slot can include resistive heaters and/or nozzles to flow gas (e.g., air, nitrogen, argon, helium, etc.) over reticle 300 to rapidly heat and/or cool reticle 300 to the predetermined temperature (e.g., 22° C.±0.2° C.), for example, for about five minutes for an initial temperature of about 22° C.±2° C.

In some aspects, conditioning phase 510 can include an RA measurement and/or an RSD measurement to determine when reticle 300 has reached the predetermined temperature (e.g., 22° C.±0.2° C.). For example, one or more alignment marks 310 and/or one or more edge alignment marks 320 on reticle 300 can be measured to determine conditioning reticle temperature 512. In some aspects, the RSD measurement can be converted to conditioning reticle temperature 512 through an FEM. In some aspects, conditioning phase 510 can include RA measurements between reticle 300 and a non-production substrate. For example, the non-production substrate can include one or more CTC wafers for alignment and/or reticle temperature calibration.

In some aspects, conditioning phase 510 can include conditioning reticle 300 in reticle stage 200 by using a fixed amount of production substrates to determine when reticle 300 has reached the predetermined temperature (e.g., 22° C.±0.2° C.). For example, if reticle 300 is a “hot” state (e.g., reticle temperature greater than 22° C.±0.2° C.) a maximum of about forty or less production substrates (e.g., about twenty-two to about twenty-six wafers) are needed to condition the production lot, whereas if reticle 300 is near the “perfectly-conditioned” state (e.g., 22° C.±0.2° C.) a minimum of about two or more production substrates (e.g., about two to about six wafers) are needed to condition the production lot.

In some aspects, conditioning phase 510 can include conditioning reticle 300 in reticle stage 200 by using decision-based and/or machine learning to determine when reticle 300 has reached the predetermined temperature (e.g., 22° C.±0.2° C.). For example, the decision-based and/or machine learning can include using a regression, a local regression, a non-parametric local regression, a kernel regression, a multivariate adaptive regression, regression trees, a Gaussian process regression, a support vector regression, splines, smoothing splines, nearest neighbors, a neural network, an adaptive window, Kalman filtering, a linear quadratic estimation, or a combination thereof.

In some aspects, conditioning phase 510 can include conditioning reticle 300 in reticle stage 200 by using KPIs based on RA and/or RSD measurements to determine when reticle 300 has reached the predetermined temperature (e.g., 22° C.±0.2° C.). For example, as shown in FIGS. 7 and 8, k4-parameter 700 and/or k18-parameter 800 can be measured and the convergence of average k4-parameter 710 and/or average k18-parameter 810 (e.g., convergence ≥90%) can be used to determine the temperature of reticle 300 and/or calibration of a reticle heating model.

Calibrating phase 520 can be configured to calibrate a reticle heating model by exposing reticle 300 and a non-production substrate to a dose of radiation. In one aspect, the initial temperature of reticle 300 at the start of calibrating phase 520 is the predetermined temperature (e.g., 22° C.±0.2° C.) in the “perfectly-conditioned” state. In one aspect, calibrating phase 520 further heats reticle 300 to a dose production temperature (e.g., greater than 22° C.±0.2° C.) in the “hot” state, as shown in calibrating reticle temperature 522. In one aspect, during calibrating phase 520, non-production substrates are exposed with a dose of radiation to allow inline calibration of the reticle heating model in the production environment itself. In one aspect, an initial estimate of parameters (e.g., x) that need to be calibrated is conducted, based on the reticle heating model (e.g., FEM) and reticle temperature (e.g., calibrating reticle temperature 522).

In some aspects, the initial estimate of parameters for the reticle heating model can be based on calibration (e.g., RA measurement) of one or more non-production substrates (e.g., CTC wafers). For example, the reticle heating model can be evaluated for one or more non-production substrates, for example, until a convergence of parameters (e.g., convergence ≥90%) in the reticle heating model is reached. In some aspects, once calibration of the reticle heating model is completed by one or more non-production substrates, production substrates in a production lot are started and calibration based on RA measurements is continued throughout processing phase 530.

In some aspects, calibrating phase 520 can include an RA measurement and/or an RSD measurement to determine the temperature of reticle 300. In some aspects, calibrating phase 520 can include inline real-time calibration of the reticle heating model based on one or more non-production substrates and/or one or more non-production lots. For example, reticle temperature in a particular phase (e.g., conditioning phase 510) can be compared between two different non-production substrates and/or non-production lots and the difference (e.g., differential reticle temperature ΔT) or trend (e.g., ΔT=0.5° C.) can be adjusted in the reticle heating model.

In some aspects, calibrating phase 520 can include evaluating the reticle heating model for each RA measurement between the reticle and a plurality of non-production substrates in a non-production lot. For example, the evaluating can include updating a parameter x (e.g., radiation dose, focus, alignment, etc.) of the lithographic process by the following:

$${x}_{n e w} = {x}_{o l d} + γ \cdot ( x - R {A}_{results} )$$

where γ is a gain value and configured to filter out noise. For example, γ can be equal to any number within the interval [−1, 1](e.g., −1, −0.5, −0.1, 0.1, 0.5, 1). For example, the evaluating can include an RA measurement of each of the plurality of non-production substrates until a convergence (e.g., ≥90%) is reached.

In some aspects, calibrating phase 520 can be further configured to acclimate (e.g., heat) reticle 300 to a dose temperature by exposing reticle 300 and a non-production substrate to a dose of radiation. In one aspect, the initial temperature of reticle 300 at the start of calibrating phase 520 is the predetermined temperature (e.g., 22° C.±0.2° C.) in the “perfectly-conditioned” state. In one aspect, calibrating phase 520 heats reticle 300 to a dose temperature (e.g., about 24° C.), as shown in calibrating reticle temperature 522. In some aspects, calibrating phase 520 can include an RA measurement and/or an RSD measurement to determine the temperature of reticle 300. In some aspects, the non-production substrate can include one or more CTC wafers for dose calibration.

Processing phase 530 can be configured to process (e.g., fabricate) a production substrate by exposing reticle 300 and the production substrate to a dose of radiation based on the reticle heating model. In one aspect, the initial temperature of reticle 300 at the start of processing phase 530 is the dose temperature (e.g., about 24° C.). In one aspect, processing phase 530 further heats reticle 300 to a dose production temperature (e.g., ≥24° C.) in the “hot” state, as shown in processing reticle temperature 532. In one aspect, during processing phase 530, production substrates are exposed with a dose of radiation to allow inline calibration of the reticle heating model in the production environment itself. In one aspect, an initial estimate of parameters (e.g., x) that need to be calibrated is conducted, based on the reticle heating model (e.g., FEM) and reticle temperature (e.g., processing reticle temperature 532).

In some aspects, processing phase 530 can be further configured to calibrate the reticle heating model by exposing reticle 300 and a production substrate to a dose of radiation. In some aspects, once calibration of the reticle heating model is completed by one or more non-production substrates (e.g., during calibrating phase 520), production substrates in a production lot are started and calibration based on RA measurements is continued throughout processing phase 530.

In some aspects, processing phase 530 can include an RA measurement and/or an RSD measurement to determine the temperature of reticle 300. In some aspects, processing phase 530 can include inline real-time calibration of the reticle heating model based on one or more production substrates and/or one or more production lots. For example, reticle temperature in a particular phase (e.g., conditioning phase 510) can be compared between two different production substrates and/or production lots and the difference (e.g., differential reticle temperature ΔT) or trend (e.g., ΔT=0.5° C.) can be adjusted in the reticle heating model.

In some aspects, processing phase 530 can include evaluating the reticle heating model for each RA measurement between the reticle and a plurality of production substrates in a production lot. For example, the evaluating can include updating a parameter x (e.g., radiation dose, focus, alignment, etc.) of the lithographic process by the following:

$${x}_{n e w} = {x}_{o l d} + γ \cdot ( {x}_{o l d} - R {A}_{results} )$$

where γ is a gain value and configured to filter out noise. For example, γ can be equal to any number within the interval [−1, 1](e.g., −1, −0.5, −0.1, 0.1, 0.5, 1). For example, the evaluating can include an RA measurement of each of the plurality of production substrates until a convergence (e.g., ≥90%) is reached.

In some aspects, reticle calibration method 500 can include performing separate RA and RSD measurements for each phase (e.g., in conditioning phase 510, calibrating phase 520, and processing phase 530). For example, RA measurements can be conducted in each phase, and RSD measurements can be conducted just once in each phase. In some aspects, the decision-based and/or machine learning used in conditioning phase 510 to determine the temperature of reticle 300 can also be used in calibrating phase 520 and/or processing phase 530.

In some aspects, reticle calibration method 500 can be implemented by computer system CL, which can act as a controller and/or a processor to control the various phases and measurements of reticle calibration method 500. In some aspects, reticle calibration method 500 can be implemented by lithographic apparatus LA, which can include a controller and/or a processor to control the various phases and measurements of reticle calibration method 500. In some aspects, reticle calibration method 500 can be implemented by a non-transitory computer readable medium program, for example, on computer system CL, which can act as a controller and/or a processor to control the various phases and measurements of reticle calibration method 500.

The aspects of reticle calibration method 500 shown in FIG. 5, for example, and the aspects of reticle calibration method 600 shown in FIG. 6 may be similar. Similar reference numbers are used to indicate features of the aspects of reticle calibration method 500 shown in FIG. 5 and the similar features of the aspects of reticle calibration method 600 shown in FIG. 6.

FIG. 6 illustrates reticle calibration method 600, according to an exemplary aspect. Reticle calibration method 600 can be configured to reduce effects of heating and/or cooling reticle 300 in a lithographic process. Reticle calibration method 600 can be further configured to increase calibration accuracy and speed of a reticle heating model and increase fabrication throughput and yield of the lithographic process. Although reticle calibration method 600 is shown in FIG. 6 as a stand-alone method and/or system, the aspects of this disclosure can be used with other apparatuses, systems, and/or methods, such as, but not limited to, lithographic apparatus LA, lithographic cell LC, computer system CL, metrology tool MT, support structure MT, patterning device MA, reticle exchange apparatus 100, reticle stage 200, reticle 300, IVR 400, and/or reticle calibration method 500.

As shown in FIG. 6, reticle calibration method 600 can include reticle temperature 602, process flow 604, conditioning phase 610, stress reducing phase 620, calibrating phase 630, and/or processing phase 640. Conditioning phase 610 can be configured to adjust an initial temperature of reticle 300 to a predetermined temperature. In one aspect, the initial temperature of reticle 300 can be in a range of about 20° C. to about 24° C., depending on where reticle 300 comes from in the lithography system (e.g., IRL, outside metrology tool MT, reticle stage 200, IRIS, etc.). For example, reticle 300 can initially be in a “hot” state (e.g., reticle temperature greater than 22° C.±0.2° C.), a “cold” state (e.g., reticle temperature less than 22° C.±0.2° C.), and a “perfectly-conditioned” state (e.g., reticle temperature is 22° C.±0.2° C.). In one aspect, conditioning phase 610 can include conditioning RA and RSD measurement 611 to determine an initial temperature of reticle 300. In one aspect, conditioning phase 610 cools and/or heats reticle 300 to the predetermined temperature (e.g., 22° C.±0.2° C.), as shown in FIG. 6 by conditioning reticle temperature 612.

In some aspects, reticle 300 can be conditioned (e.g., heated and/or cooled) by the IRL. For example, reticle 300 can be placed in the IRL for about forty minutes to reach the predetermined temperature (e.g., 22° C.±0.2° C.). In some aspects, reticle 300 can be conditioned (e.g., heated and/or cooled) by a conditioning slot that rapidly heats and/or cools reticle 300 to the predetermined temperature (e.g., 22° C.±0.2° C.). For example, the conditioning slot can include resistive heaters and/or nozzles to flow gas (e.g., air, nitrogen, argon, helium, etc.) over reticle 300 to rapidly heat and/or cool reticle 300 to the predetermined temperature (e.g., 22° C.±0.2° C.), for example, for about five minutes for an initial temperature of about 22° C.±2° C.

In some aspects, conditioning phase 610 can include one or more RA measurements and an RSD measurement to determine when reticle 300 has reached the predetermined temperature (e.g., 22° C.±0.2° C.). For example, as shown in FIG. 6, conditioning RA and RSD measurement 611 can be conducted to determine an initial temperature of reticle 300 in conditioning phase 610. For example, one or more alignment marks 310 (shown in FIGS. 3A and 3B) and one or more edge alignment marks 320 (shown in FIGS. 3A and 3B) on reticle 300 can be measured to determine conditioning reticle temperature 612. In some aspects, the RSD measurement can be converted to conditioning reticle temperature 612 through an FEM. In some aspects, conditioning phase 610 can include one or more RA measurements between reticle 300 and a non-production substrate. For example, as shown in FIG. 6, conditioning phase 610 can include conditioning RA and RSD measurement 611, second conditioning RA measurement 614 (if needed), third conditioning RA measurement 616 (if needed), and/or fourth conditioning RA measurement 618 (if needed) to measure reticle temperature 602 periodically during process flow 604 and determine when reticle 300 has reached the predetermined temperature (e.g., 22° C.±0.2° C.). For example, the non-production substrate can include one or more CTC wafers for alignment and/or reticle temperature calibration.

In some aspects, conditioning phase 610 can include conditioning reticle 300 in reticle stage 200 by using a fixed amount of production substrates to determine when reticle 300 has reached the predetermined temperature (e.g., 22° C.±0.2° C.). For example, if reticle 300 is in a “hot” state (e.g., reticle temperature greater than 22° C.±0.2° C.) a maximum of about forty or less production substrates (e.g., about twenty-two to about twenty-six wafers) are needed to condition the production lot, whereas if reticle 300 is near the “perfectly-conditioned” state (e.g., 22° C.±0.2° C.) a minimum of about two or more production substrates (e.g., about two to about six wafers) are needed to condition the production lot.

In some aspects, conditioning phase 610 can include conditioning reticle 300 in reticle stage 200 by using decision-based and/or machine learning to determine when reticle 300 has reached the predetermined temperature (e.g., 22° C.±0.2° C.). For example, the decision-based and/or machine learning can include using a regression, a local regression, a non-parametric local regression, a kernel regression, a multivariate adaptive regression, regression trees, a Gaussian process regression, a support vector regression, splines, smoothing splines, nearest neighbors, a neural network, an adaptive window, Kalman filtering, a linear quadratic estimation, or a combination thereof. In some aspects, the timing specifications (e.g., applied Kalman filtering) are aligned with the timing specification of the lithographic process (e.g., process window) with similar high accuracy. In some aspects, an adaptive window can be used to determine whether there is any decay and/or drift of KPIs (e.g., k4-parameter, k18-parameter). For example, four RA measurements can be conducted (e.g., past three measurements and current measurement) and a check can be performed to verify whether any variation between the RA measurements has occurred. If a variation is detected, conditioning phase 610 continues, whereas if no variation is detected, conditioning phase 610 is completed (e.g., stopped). In some aspects, a minimum time of conditioning phase 610 is about one minute and a maximum time of conditioning phase 610 is about five minutes.

In some aspects, conditioning phase 610 can include conditioning reticle 300 in reticle stage 200 by using KPIs based on RA and/or RSD measurements to determine when reticle 300 has reached the predetermined temperature (e.g., 22° C.±0.2° C.). For example, as shown in FIGS. 7 and 8, k4-parameter 700 and/or k18-parameter 800 can be measured and the convergence of average k4-parameter 710 and/or average k18-parameter 810 (e.g., convergence ≥90%) can be used to determine the temperature of reticle 300 and/or calibration parameters of a reticle heating model. For example, as shown in FIG. 6, conditioning phase 610 can include conditioning RA and RSD measurement 611, second conditioning RA measurement 614, third conditioning RA measurement 616, and/or fourth conditioning RA measurement 618 to measure KPIs (e.g., k4-parameter 700, k18-parameter 800) to determine when reticle 300 has reached the predetermined temperature (e.g., 22° C.±0.2° C.).

Stress reducing phase 620 can be configured to reduce parasitic thermal effects in reticle 300. In one aspect, as shown in FIG. 6, stress reducing phase 620 can include removal step 621 and zero dose step 622. Removal step 621 can be configured to release stress from reticle 300 by removing reticle 300 from reticle stage 200 to IVR 400 and thereby reduce parasitic thermal effects. Zero dose step 622 can be configured to release stress from reticle 300 by exposing reticle 300 and a non-production substrate to a zero dose of radiation and thereby reduce parasitic thermal effects. In one aspect, the initial temperature of reticle 300 at the start of stress reducing phase 620 is the predetermined temperature (e.g., 22° C.±0.2° C.) in the “perfectly-conditioned” state. In one aspect, stress reducing phase 620 reduces parasitic thermal effects in reticle 300 by releasing stress in reticle 300 in removal step 621 and then exposing reticle 300 in zero dose step 622 to further reduce parasitic thermal effects, as shown in stress reducing reticle temperature 624. In one aspect, stress reducing phase 620 maintains reticle 300 at the predetermined temperature (e.g., 22° C.±0.2° C.) in the “perfectly-conditioned” state. In one aspect, zero dose step 622 can include zero dose RA and RSD measurement 623 to verify the temperature of reticle 300.

In some aspects, stress can be reduced in reticle 300 by removing reticle 300 from reticle stage 200 and quickly returning reticle 300 back to reticle stage 200. For example, as shown in FIGS. 4A and 4B, reticle 300 can be unclamped from reticle cages 224 and clamp 250 on reticle stage 200 and transferred to reticle baseplate 406 of IVR 400, and then immediately transferred back to reticle stage 200 and clamped by reticle cages 224 and clamp 250. In some aspects, stress can be reduced in reticle 300 by exposing reticle 300 and a non-production substrate (e.g., CTC wafer) to a zero dose of radiation. For example, as shown in FIG. 6, after removal step 621, zero dose step 622 can begin and reticle temperature can once again be verified (e.g., via RA and/or RSD measurements). In some aspects, stress reducing phase 620 can include an RA measurement and/or an RSD measurement to determine the temperature of reticle 300. For example, as shown in FIG. 6, zero dose RA and RSD measurement 623 can be conducted to verify an initial temperature of reticle 300 in zero dose step 622. In some aspects, the non-production substrate can include one or more CTC wafers for zero dose calibration.

Calibrating phase 630 can be configured to calibrate a reticle heating model by exposing reticle 300 and a non-production substrate to a dose of radiation. In one aspect, the initial temperature of reticle 300 at the start of calibrating phase 630 is the predetermined temperature (e.g., 22° C.±0.2° C.) in the “perfectly-conditioned” state. In one aspect, calibrating phase 630 can include calibrating RA and RSD measurement 631 to verify the temperature of reticle 300. In one aspect, calibrating phase 630 heats reticle 300 to a dose temperature (e.g., greater than 22° C.±0.2° C.), as shown in calibrating reticle temperature 632. In one aspect, during calibrating phase 630, non-production substrates are exposed with a dose of radiation to allow inline calibration of the reticle heating model in the production environment itself. In one aspect, an initial estimate of parameters (e.g., x) that need to be calibrated is conducted, based on the reticle heating model (e.g., FEM) and reticle temperature (e.g., calibrating reticle temperature 632).

In some aspects, the initial estimate of parameters for the reticle heating model can be based on calibration (e.g., RA measurement) of one or more non-production substrates (e.g., CTC wafers). For example, the reticle heating model can be evaluated for one or more non-production substrates, for example, until a convergence of parameters (e.g., convergence ≥90%) in the reticle heating model is reached. In some aspects, once calibration of the reticle heating model is completed by one or more non-production substrates, production substrates in a production lot are started and calibration based on RA measurements is continued throughout processing phase 640.

In some aspects, calibrating phase 630 can include an RA measurement and/or an RSD measurement to determine the temperature of reticle 300. For example, as shown in FIG. 6, calibrating RA and RSD measurement 631 can be conducted to verify an initial temperature of reticle 300 at the start of calibrating phase 630. In some aspects, calibrating phase 630 can include inline real-time calibration of the reticle heating model based on one or more non-production substrates and/or one or more non-production lots. For example, reticle temperature in a particular phase (e.g., conditioning phase 610) can be compared between two different non-production substrates and/or non-production lots and the difference (e.g., differential reticle temperature ΔT) or trend (e.g., ΔT=0.5° C.) can be adjusted in the reticle heating model.

In some aspects, calibrating phase 630 can include evaluating the reticle heating model for each RA measurement between reticle 300 and a plurality of non-production substrates in a non-production lot. For example, the evaluating can include updating a parameter x (e.g., radiation dose, focus, alignment, etc.) of the lithographic process by the following:

$${x}_{n e w} = {x}_{o l d} + γ \cdot ( x - R {A}_{results} )$$

where γ is a gain value and configured to filter out noise. For example, γ can be equal to any number within the interval [−1, 1](e.g., −1, −0.5, −0.1, 0.1, 0.5, 1). For example, the evaluating can include an RA measurement of each of the plurality of non-production substrates until a convergence (e.g., ≥90%) is reached.

In some aspects, calibrating phase 630 can be further configured to acclimate (e.g., heat) reticle 300 to a dose temperature by exposing reticle 300 and a non-production substrate to a dose of radiation. In one aspect, the initial temperature of reticle 300 at the start of calibrating phase 630 is the predetermined temperature (e.g., 22° C.±0.2° C.) in the “perfectly-conditioned” state. In one aspect, calibrating phase 630 heats reticle 300 to a dose temperature (e.g., about 24° C.), as shown in calibrating reticle temperature 632. In some aspects, calibrating phase 630 can include an RA measurement and/or an RSD measurement to determine the temperature of reticle 300. For example, as shown in FIG. 6, calibrating RA and RSD measurement 631 can be conducted to verify an initial temperature of reticle 300 in calibrating phase 630. In some aspects, the non-production substrate can include one or more CTC wafers for dose calibration.

Processing phase 640 can be configured to process (e.g., fabricate) a production substrate by exposing reticle 300 and the production substrate to a dose of radiation based on the reticle heating model. In one aspect, the initial temperature of reticle 300 at the start of processing phase 640 is the dose temperature (e.g., about 24° C.). In one aspect, processing phase 640 can include processing RA and RSD measurement 641 to verify the temperature of reticle 300. In one aspect, processing phase 640 further heats reticle 300 to a dose production temperature (e.g., ≥24° C.) in the “hot” state, as shown in processing reticle temperature 642. In one aspect, during processing phase 640, production substrates are exposed with a dose of radiation to allow inline calibration of the reticle heating model in the production environment itself. In one aspect, an initial estimate of parameters (e.g., x) that need to be calibrated is conducted, based on the reticle heating model (e.g., FEM) and reticle temperature (e.g., processing reticle temperature 642).

In some aspects, processing phase 640 can be further configured to calibrate the reticle heating model by exposing reticle 300 and a production substrate to a dose of radiation. In some aspects, once calibration of the reticle heating model is completed by one or more non-production substrates (e.g., during calibrating phase 630), production substrates in a production lot are started and calibration based on RA measurements is continued throughout processing phase 640.

In some aspects, processing phase 640 can include an RA measurement and/or an RSD measurement to determine the temperature of reticle 300. For example, as shown in FIG. 6, processing RA and RSD measurement 641 can be conducted to verify an initial temperature of reticle 300 at the start of processing phase 640. In some aspects, processing phase 640 can include inline real-time calibration of the reticle heating model based on one or more production substrates and/or one or more production lots. For example, reticle temperature in a particular phase (e.g., conditioning phase 610) can be compared between two different production substrates and/or production lots and the difference (e.g., differential reticle temperature ΔT) or trend (e.g., ΔT=0.5° C.) can be adjusted in the reticle heating model.

In some aspects, processing phase 640 can include evaluating the reticle heating model for each RA measurement between reticle 300 and a plurality of production substrates in a production lot. For example, the evaluating can include updating a parameter x (e.g., radiation dose, focus, alignment, etc.) of the lithographic process by the following:

$${x}_{n e w} = {x}_{o l d} + γ \cdot ( x - R {A}_{results} )$$

where γ is a gain value and configured to filter out noise. For example, γ can be equal to any number within the interval [−1, 1](e.g., −1, −0.5, −0.1, 0.1, 0.5, 1). For example, the evaluating can include an RA measurement of each of the plurality of production substrates until a convergence (e.g., ≥90%) is reached.

In some aspects, reticle calibration method 600 can include performing separate RA and RSD measurements for each phase (e.g., in conditioning phase 610, stress reducing phase 620, calibrating phase 630, and processing phase 640). For example, RA measurements can be conducted in each phase, and RSD measurements can be conducted just once in each phase. In some aspects, the decision-based and/or machine learning used in conditioning phase 610 to determine the temperature of reticle 300 can also be used in stress reducing phase 620, calibrating phase 630, and/or processing phase 640.

In some aspects, reticle calibration method 600 can utilize a comprehensive reticle heating model to cover all possible heating dynamics. For example, reticle calibration method 600 can avoid calibrating phase 630 by using one or more pre-determined FEM in the reticle heating model. In some aspects, reticle calibration method 600 can utilize a central data pool to calibrate the reticle heating model. For example, the central data pool can include baseline and/or statistical values (e.g., parameters of the reticle heating model) based on various internal (e.g., in-resist) data. In some aspects, reticle calibration method 600 can include sine-sweep exposures to conduct both reticle heating model calibration and lens calibration. For example, by using sine-sweep exposures (e.g., fixed period), different time constants can be extracted (e.g., with RA and/or RSD measurements) for reticle heating model parameters and lens parameters for calibration.

In some aspects, reticle calibration method 600 can be implemented by computer system CL, which can act as a controller and/or a processor to control the various phases and measurements of reticle calibration method 600. In some aspects, reticle calibration method 600 can be implemented by lithographic apparatus LA, which can include a controller and/or a processor to control the various phases and measurements of reticle calibration method 600. In some aspects, reticle calibration method 600 can be implemented by a non-transitory computer readable medium program, for example, on computer system CL, which can act as a controller and/or a processor to control the various phases and measurements of reticle calibration method 600.

FIG. 7 illustrates k4-parameter 700, according to an exemplary aspect. K4-parameter 700 can be configured to increase calibration accuracy and speed of a reticle heating model. K4-parameter 700 can be further configured to determine a temperature of reticle 300. K4-parameter 700 represents distortion in Y-axis magnification. Although k4-parameter 700 is shown in FIG. 7 as a stand-alone method and/or system, the aspects of this disclosure can be used with other apparatuses, systems, and/or methods, such as, but not limited to, lithographic apparatus LA, lithographic cell LC, computer system CL, metrology tool MT, reticle calibration method 500, and/or reticle calibration method 600.

As shown in FIG. 7, k4-parameter 700 can include intensity (arbitrary units) 702, wafer number 704, and average k4-parameter 710. In some aspects, k4-parameter 700 can be measured based on distortions in RA and/or RSD measurements to determine a temperature of reticle 300. For example, as shown in FIG. 7, average k4-parameter 710 can be measured over several wafers and the convergence (e.g., ≥90%) of average k4-parameter 710 can be used to determine the temperature of reticle 300 and/or calibration parameters of the reticle heating model of reticle calibration method 500 and/or reticle calibration method 600. In some aspects, k4-parameter 700 can be measured to determine when reticle 300 has reached a predetermined temperature (e.g., 22° C.±0.2° C.).

FIG. 8 illustrates k18-parameter 800, according to an exemplary aspect. K18-parameter 800 can be configured to increase calibration accuracy and speed of a reticle heating model. K18-parameter 800 represents distortion in Y-axis barrel shape. Although k18-parameter 800 is shown in FIG. 8 as a stand-alone method and/or system, the aspects of this disclosure can be used with other apparatuses, systems, and/or methods, such as, but not limited to, lithographic apparatus LA, lithographic cell LC, computer system CL, metrology tool MT, reticle calibration method 500, and/or reticle calibration method 600.

As shown in FIG. 8, k18-parameter 800 can include intensity (arbitrary units) 802, wafer number 804, and average k18-parameter 810. In some aspects, k18-parameter 800 can be measured based on distortions in RA and/or RSD measurements to determine a temperature of reticle 300. For example, as shown in FIG. 8, average k18-parameter 810 can be measured over several wafers and the convergence (e.g., ≥90%) of average k18-parameter 810 can be used to determine the temperature of reticle 300 and/or calibration parameters of the reticle heating model of reticle calibration method 500 and/or reticle calibration method 600. In some aspects, k18-parameter 800 can be measured to determine when reticle 300 has reached a predetermined temperature (e.g., 22° C.±0.2° C.).

### Exemplary Reticle Calibration Diagrams

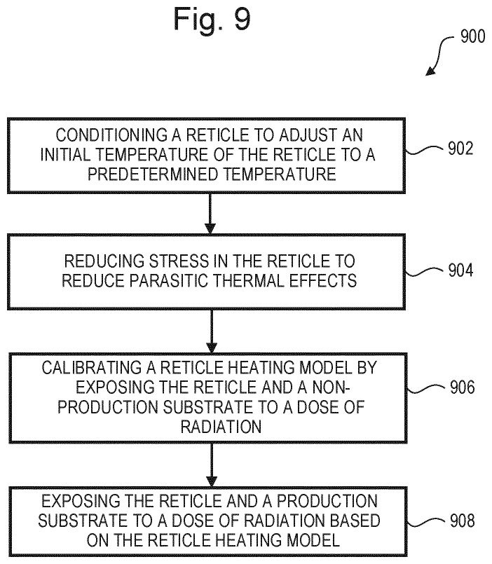

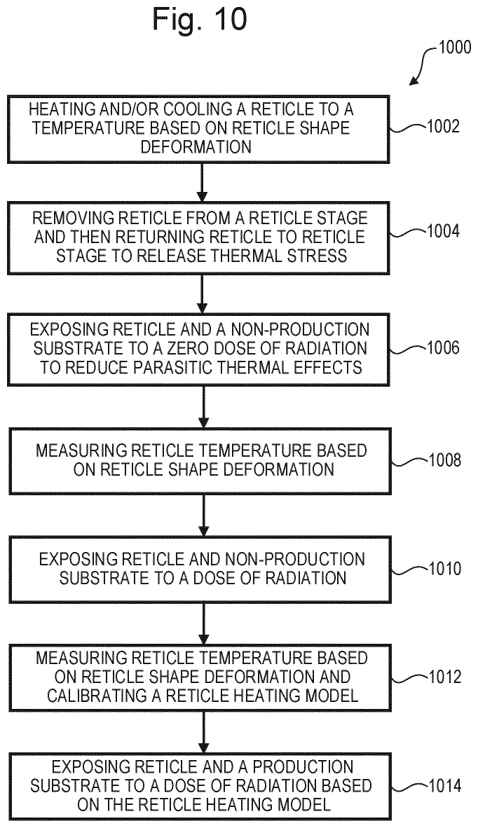

FIGS. 9 and 10 illustrate reticle calibration diagrams 900, 1000 for reducing effects of heating and/or cooling reticle 300 in a lithographic process, according to exemplary aspects. FIG. 9 illustrates reticle calibration diagram 900, according to an exemplary aspect. It is to be appreciated that not all steps in FIG. 9 are needed to perform the disclosure provided herein. Further, some of the steps may be performed simultaneously, sequentially, and/or in a different order than shown in FIG. 9. Reticle calibration diagram 900 shall be described with reference to FIGS. 3A, 3B, 4A, 4B, 5 and 6. However, reticle calibration diagram 900 is not limited to those example aspects.

In step 902, as shown in the example of FIGS. 3A, 3B, 5, and 6, reticle 300 is conditioned (e.g., heated and/or cooled) to adjust an initial temperature of reticle 300 to a predetermined temperature (e.g., 22° C.±0.2° C.). In some aspects, reticle 300 can be conditioned (e.g., heated and/or cooled) by a conditioning slot that rapidly heats and/or cools reticle 300 to the predetermined temperature (e.g., 22° C.±0.2° C.). In some aspects, one or more RA measurements and an RSD measurement can be conducted to determine when reticle 300 has reached the predetermined temperature (e.g., 22° C.±0.2° C.). In some aspects, decision-based and/or machine learning can be used to determine when reticle 300 has reached the predetermined temperature (e.g., 22° C.±0.2° C.).

In step 904, as shown in the example of FIGS. 3A, 3B, 4A, 4B, and 6, stress in reticle 300 is reduced (e.g., released) and parasitic thermal effects in reticle 300 are reduced. In some aspects, stress in reticle 300 can be released by removing reticle 300 from reticle stage 200 to IVR 400 and thereby reduce parasitic thermal effects. In some aspects, stress in reticle 300 can be released by exposing reticle 300 and a non-production substrate to a zero dose of radiation and thereby reduce parasitic thermal effects.

In step 906, as shown in the example of FIGS. 3A, 3B, 5, and 6, a reticle heating model is calibrated by exposing reticle 300 and a non-production substrate to a dose of radiation. In some aspects, an initial estimate of parameters for the reticle heating model can be based on calibration (e.g., RA measurement) of one or more non-production substrates (e.g., CTC wafers). In some aspects, an RA measurement and/or an RSD measurement can be conducted to determine the temperature of reticle 300. In some aspects, inline real-time calibration of the reticle heating model can be based on one or more non-production substrates and/or one or more non-production lots. In some aspects, the reticle heating model can be evaluated for each RA measurement between reticle 300 and a plurality of non-production substrates in a non-production lot.

In some aspects, during step 906, reticle 300 is acclimated (e.g., heated) by exposing reticle 300 and a non-production substrate to a dose of radiation. In some aspects, an RA measurement and/or an RSD measurement can be conducted to determine the temperature of reticle 300. In some aspects, the non-production substrate can include one or more CTC wafers for dose calibration.

In step 908, as shown in the example of FIGS. 3A, 3B, 5, and 6, a production substrate is processed (e.g., fabricated) by exposing reticle 300 and the production substrate to a dose of radiation based on the reticle heating model. In some aspects, an RA measurement and/or an RSD measurement can be conducted to determine the temperature of reticle 300. In some aspects, inline real-time calibration of the reticle heating model can be based on one or more production substrates and/or one or more production lots. In some aspects, the reticle heating model can be evaluated for each RA measurement between reticle 300 and a plurality of production substrates in a production lot.

FIG. 10 illustrates reticle calibration diagram 1000, according to an exemplary aspect. It is to be appreciated that not all steps in FIG. 10 are needed to perform the disclosure provided herein. Further, some of the steps may be performed simultaneously, sequentially, and/or in a different order than shown in FIG. 10. Reticle calibration diagram 1000 shall be described with reference to FIGS. 3A, 3B, 4A, 4B, 5 and 6. However, reticle calibration diagram 1000 is not limited to those example aspects.

In step 1002, as shown in the example of FIGS. 3A, 3B, 5, and 6, reticle 300 is heated and/or cooled to a temperature (e.g., 22° C.±0.2° C.) based on an RSD measurement. In some aspects, the RSD measurement can be converted to reticle temperature through an FEM. In some aspects, reticle 300 can be heated and/or cooled by a conditioning slot that rapidly heats and/or cools reticle 300. In some aspects, one or more RA measurements and an RSD measurement can be conducted to determine when reticle 300 has reached a predetermined temperature (e.g., 22° C.±0.2° C.). In some aspects, decision-based and/or machine learning can be used to determine when reticle 300 has reached a predetermined temperature (e.g., 22° C.±0.2° C.).

In step 1004, as shown in the example of FIGS. 3A, 3B, 4A, 4B, and 6, reticle 300 is removed from reticle stage 200 and then returned to reticle stage 200 to release thermal stress. In some aspects, stress in reticle 300 (e.g., induced stress, internal strain) can be released by removing reticle 300 from reticle stage 200 to IVR 400 and quickly returning reticle 300 from IVR 400 to reticle stage 200, thereby reducing parasitic thermal effects.

In step 1006, as shown in the example of FIGS. 3A, 3B, and 6, reticle 300 and a non-production substrate are exposed to a zero dose of radiation to reduce parasitic thermal effects. In some aspects, stress in reticle 300 (e.g., residual stress) can be released and/or relaxed by exposing reticle 300 and a non-production substrate (e.g., CTC wafer) to a zero dose of radiation, thereby reducing parasitic thermal effects.

In step 1008, as shown in the example of FIGS. 3A, 3B, 5, and 6, temperature of reticle 300 is measured based on an RSD measurement. In some aspects, an RA measurement and/or an RSD measurement can be conducted to determine the temperature of reticle 300.

In step 1010, as shown in the example of FIGS. 3A, 3B, 5, and 6, reticle 300 and a non-production substrate are exposed to a dose of radiation. In some aspects, an RA measurement and/or an RSD measurement can be conducted to determine the temperature of reticle 300. In some aspects, the non-production substrate can include one or more CTC wafers for dose calibration.

In step 1012, as shown in the example of FIGS. 3A, 3B, 5, and 6, temperature of reticle 300 is measured based on an RSD measurement and a reticle heating model is calibrated based on the measured temperature of reticle 300. In some aspects, an RA measurement and/or an RSD measurement can be conducted to determine the temperature of reticle 300. In some aspects, an initial estimate of parameters for the reticle heating model can be based on calibration (e.g., RA measurement) of one or more non-production substrates (e.g., CTC wafers). In some aspects, an RA measurement and/or an RSD measurement can be conducted to determine the temperature of reticle 300. In some aspects, inline real-time calibration of the reticle heating model can be based on one or more non-production substrates and/or one or more non-production lots. In some aspects, the reticle heating model can be evaluated for each RA measurement between reticle 300 and a plurality of non-production substrates in a non-production lot.

In step 1014, as shown in the example of FIGS. 3A, 3B, 5, and 6, a production substrate is processed (e.g., fabricated) by exposing reticle 300 and the production substrate to a dose of radiation based on the reticle heating model. In some aspects, an RA measurement and/or an RSD measurement can be conducted to determine the temperature of reticle 300. In some aspects, inline real-time calibration of the reticle heating model can be based on one or more production substrates and/or one or more production lots. In some aspects, the reticle heating model can be evaluated for each RA measurement between reticle 300 and a plurality of production substrates in a production lot.

The above-described techniques allow reticle heating calibration (RHC) data to be determined. RHC data provides information on how a reticle heats from a cold state. RHC data may be used to improve the accuracy of an estimation of the deformation of a reticle in dependence on an RA measurement.

FIGS. 5 and 6 show a conditioning phase, a calibrating phase and a processing phase. In each of these phases, the temperature of the reticle changes over a temperature range. RA measurements may be made with the reticle at the different temperatures within each temperature range. As described above, a model, such as a FEM model, may be used to determine the stresses that are generated and the resulting deformation of the reticle. RHC data may be generated in dependence on the RA measurements at different temperatures, and the corresponding stresses and deformations at each temperature. The RHC data thereby allows a determination of how a reticle heats from a cold state and the stresses, and deformations, that occur. The deformations may be determined as deformation modes, such as the earlier described k-parameters.

According to a first embodiment, RHC data is used to improve the accuracy of a reticle heating model. The reticle heating model may comprise the earlier described RHEA. The RHEA is a modal deformation approach with the modelled deformation dependent on RA measurements.

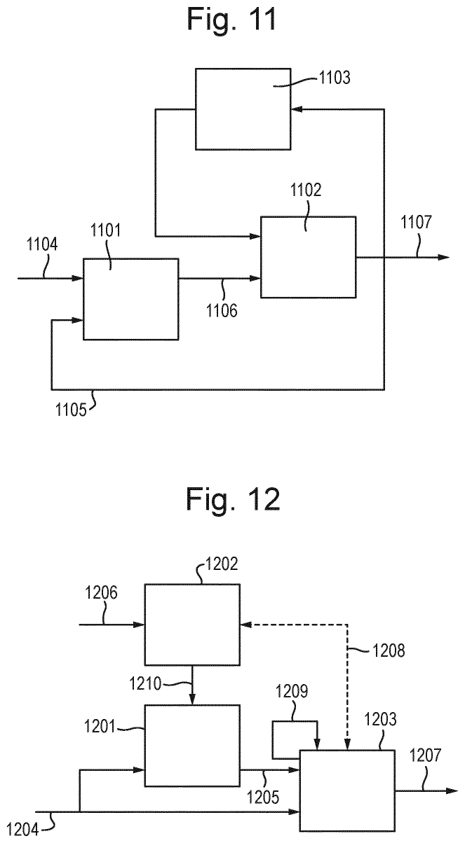

FIG. 11 shows a deterministic reticle heating model. The model comprises a RHEA 1101, a reticle heating module 1102 and an uncertainty module 1103.

The inputs to the RHEA may include a nominal reference state 1104 and RA feedback data 1105. The nominal reference state 1104 is data describing the initial state of a reticle. The nominal reference state 1104 may be retrieved from a library. The RA feedback data 1105 may comprise operational data, such as the applied dose. The RHEA output 1106 may comprise heating dynamics determined by the RHEA 1101. The RHEA output 1106 may be provided to the reticle heating module 1102.

The uncertainty module 1103 represents contributions to the actual deformation of a reticle that the deterministic reticle heating module is unable to predict. In particular, the uncertainties may include events such as timing changes, or changes that result in different boundary conditions.

The reticle heating module 1102 may determine and output mode shapes that are a determination of the reticle deformation. Process corrections for changing the operation of the lithographic apparatus may be determined in dependence on the output of the reticle heating model to at least partially compensate for the reticle deformation.

A problem with the reticle heating model in FIG. 11 is that the accuracy of the model is dependent on the reference state 1104 that describes the initial state of the reticle. The reference state 1104 assumes that the reticle is perfectly conditioned. The accuracy of the reticle heating model may therefore substantially decrease if the reticle is not perfectly conditioned.

The actual arrival temperature of a reticle is dependent on the history of the reticle and may vary between about 20° C. and 24° C. For example, if a reticle is delivered from outside of the lithographic apparatus, the reticle temperature will depend on the temperature within the manufacturing plant. If a reticle is provided by the reticle stage, the reticle temperature will depend the number of exposure processes that have been performed with the reticle, as well as the doses of the exposure processes. If a reticle is provided from a thermal conditioning slot, the reticle temperature will depend on the type of thermal conditioning slot and the length of time that the reticle was in the conditioning slot.

An operator of the lithographic apparatus therefore faces the choice of either decreasing the overlay performance by using a reticle that is not appropriately conditioned, or slowing down the operation of the lithographic apparatus to allow all used reticles to be appropriately conditioned.

According to a first embodiment, the above problem is solved by providing a reticle heating model that may determine the deformation of a reticle with improved accuracy when the reticle is not perfectly conditioned.

FIG. 12 shows a new deterministic reticle heating model according to the present embodiment. The model according to the present embodiment improves on the model shown in FIG. 11 by applying a calibration to the nominal reference state 1104. The applied calibration improves the accuracy of the model by at least partially reducing the effect of the variable initial temperature of a reticle.

The model comprises a RHEA 1203, a reticle reference module, RRM, 1202 and a reference masker, RM, module 1201.

The RRM inputs 1206 may include a nominal reference state. The input nominal reference state, that may be retrieved from a library, may be the same reference state 1104 described earlier that is nominal data describing the initial state of a reticle.

The RRM inputs 1206 may also include the earlier described RHC data.

The RRM inputs 1206 may also include reticle handling data that may be received from the reticle handler 402. The reticle handling data may include data on how the reticle has been handled. The reticle handling data may include location data that describes the location where the reticle has been. The reticle handling data may include time data that describes how long the reticle has been at each location. The reticle handling data may include thermal data that describes the temperature at each location that the reticle has been. The reticle handling data may include data on the thermal properties of the reticle at each location.

The RRM inputs 1206 may also include the current and/or previous outputs from the RHEA 1203 as well as other data.

The RRM 1202 may receive updated inputs for each lot of substrates that are being processed and/or whenever there is an event with the reticle handler 402.

The RRM output 1210 may be data that the RRM 1202 receives, or data generated in dependence on the data that the RRM 1202 receives. The RRM output 1210 may be an input to the RM 1201. The RRM 1202 may provide the RRM output 1210 when the first RA measurement with a reticle is made for each use of the reticle.

The RM inputs 1204 may also include RA measurement data and exposure data. The RM inputs 1204 may be provided to the RM 1201 when the first RA measurement with a reticle is made for each use of the reticle.

The RM 1201 may generate a calibrated reference state 1205 independence on the data received by the RM 1201. The calibrated reference state is an determination of the shape and properties of the reticle when the reticle is in a cold state. The RM output 1205 comprises the calibrated reference state. The RM 1201 may provide the RM output 1205 when the first RA measurement with a reticle is made for each use of the reticle.

The RHEA 1203 may receive the RM output 1205 as an input.

There may also be communication path 1208 between the RHEA 1203 and the RRM 1202. The communication path may allow the communication of operational data, such as whether a hiccup or other processing delay has occurred.

The RHEA input 1204 may also include RA measurement data and exposure data. The RHEA input 1204 may be provided to the RHEA 1203 after each RA measurement and/or exposure process is performed.

The RHEA may also receive RA feedback data 1209. The RA feedback data 1209 may be provided to the RHEA 1203 for each lot of substrates that are being processed and/or whenever there is an event with the reticle handler 402. The RA feedback data 1209 may be the same as the RA feedback data as described earlier with reference to FIG. 11.

The RHEA 1203 may use the received inputs to determine heating dynamics. In particular, the RHEA 1203 may determine the current shape of a reticle in dependence on determinations of the shape of the reticle when the reticle is in a cold state, the current temperature of the reticle (that may be estimated from an RA measurement), and data on how the shape of the reticle changes as it is heated from its cold state to its current temperature (as provided by the RHC data). The RHEA 1203 may thereby perform more accurate determinations than techniques based only on a nominal reference state 1104 without any calibration given the current temperature of the reticle.

The RHEA output 1207 may comprise heating dynamics that may be input to a reticle heating module 1102 for determining and outputting mode shapes that are a determination of the deformation of a reticle, as described earlier with reference to FIG. 11. Alternatively, there may be no reticle heating module 1102 and the RHEA output 1207 may comprise a determination of mode shapes that are a determination of the deformation of a reticle.

The RHEA output 1207 may be output from the RHEA 1203 after each RA measurement and/or exposure process is performed.

The operation of the present embodiment is described in more detail below.

At the start of processing a lot of substrates, the temperature of the reticle may be unknown and the reticle may be in a hot state or a cold state.

An RA measurement may be made. The RA measurement may input to the RM 1201. The RM 1201 may use data received by the RRM 1202 to determine reference shape data of the reticle. The RM 1201 may estimate reference reticle alignment data as:

$$\text{?} = E ( F ( reference shape data ) , F ( first reticle align ) ) {\vert}_{RHC - KPIs}$$

In the above equation, [symbol] a is estimated reference reticle alignment data based on measured and stored reticle shape data. The measured and stored reticle shape data is filtered, as shown by F( . . . ), to remove any preexisting systematic effects with respect to reticle heating calibration KPIs (e.g. r4, r18, r10 etc.).

The calibration process may separate the stress effects from the thermomechanical effects of the reticle heating behavior. Stress induced effects may thereby be differentiated and reduced. As described earlier with reference to FIG. 6, a reticle may be cooled in a conditioning phase during which stresses are present in the reticle. A stress reducing phase may then be performed that substantially reduces the stresses. The substantially unstressed reticle may then be heated, in the calibrating phase and processing phase, across a temperature range that substantially overlaps with the temperature range over which the reticle was cooled during the conditioning phase. The stress effects may be determined from a comparison of the stressed and substantially unstressed states of the reticle. In particular, a filtering operation, F( . . . ), may be performed to remove any systematic effects. With Phase₁ representing the conditioning phase and Phase_{2,3} representing the calibrating phase and/or processing phase, the comparison of the stressed and substantially unstressed states of the reticle may determine Δₛₜᵣₑₛₛ as:

$${Δ}_{stress} = E ( F ( {Phase}_{1} ) , F ( {Phase}_{2 , 3} ) ) {\vert}_{RHC - KPIs}$$

The Δₛₜᵣₑₛₛ may be used to determine the calibrated reference, Ref_{cal}, as:

$${Ref}_{cal} = E ( {Δ}_{sfress} , \text{?} ) {\vert}_{RHC - KPIs}$$

The calibrated reference may be used to determine the shape of a reticle in its cold state. This may be used to appropriately model the state of the reticle in its current state, despite variations in the incoming temperature of the reticle.

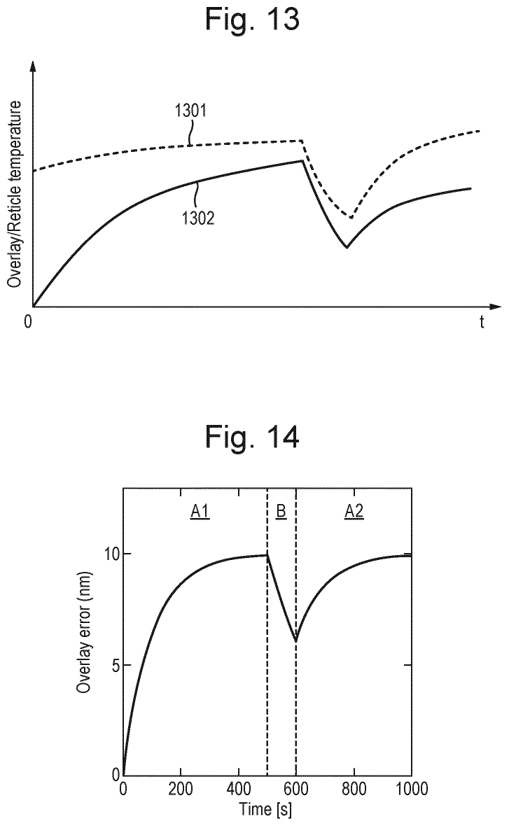

FIG. 13 shows the differences in the modelled ratio of overlay to reticle temperature as lots of substrates W are processed for both a known model 1302 and the new model 1301 according to the present embodiment.

In FIG. 13, the y-axis represents the modelled ratio of overlay to reticle temperature. The x-axis represents the time during which lots of substrates are processed. The known model 1302 does not use a calibrated reference state of the reticle and incorrectly assumes that the reticle is perfectly conditioned. The model 1301 according to the present embodiment improves on the known model by using the calibrated reference to determine a calibrated reference state 1205. The calibrated reference state 1205 may be used with all of the substrates in each lot. For each separate lot of substrates, the shape of the reticle in its cold state may be determined and the current shape of the reticle appropriately determined.

The present embodiment improves the accuracy of the modelled state of a reticle. The applied process corrections in response to the modelled reticle deformation are thereby more appropriate and the overlay performance is thereby improved, without reducing the productivity of the system. The performance of the model may be less sensitive to the temperature variation of a reticle. The accuracy of the model is therefore improved when a reticle that is not in a perfectly conditioned state is used. The overlay impact caused by a hot reticle being used may be reduced by about half and the sensitivity of the system to variation in applied process corrections is reduced. The present embodiment does not require a temperature sensor for measuring the temperature of the reticle.

According to a second embodiment, a technique is provided for improving the accuracy of a reticle heating model when fast lot transitions occur.

The lithographic processes performed on a substrate may comprise using a first reticle on a lot of substrates, using a second reticle on the lot of substrates, and then re-using the first reticle on the lot of substrates. This may occur when, for example, when a first pattern is required on a first layer of a substrate, a second pattern is required on a second layer of a substrate, and the same first pattern is required again on a third layer of a substrate.

Before the first reticle is first used, it may initially be in a cold state and appropriately conditioned in an IRL for use. The first reticle may then be heated as it is used in the first lithographic process performed on the lot of substrates. The first reticle is then not used when the lithographic processes are performed with the second reticle and so the first reticle cools during this period. The first reticle is then re-used. The time period between the end of the first use of the first reticle and the re-use of the first reticle may be insufficient for the first reticle to cool down to a cold state.

FIG. 14 schematically shows the overlay error that may be caused by the temperature of the reticle if processes for not correcting this source of overlay error are not performed. In the time period A1, a reticle is used and it is heated. In the time period B, the reticle is not used and it cools down. In the time period A2, the reticle is re-used. FIG. 14 illustrates that when the time period B is short, the reticle is unable to cool down to the same cold state as at the start of time period A1. If the reticle heating model assumes that the reticle at the start of time period A2 is in the cold state, then the modelled deformation of the reticle will be inaccurate. The determined process corrections for compensating for the heating of the reticle will therefore also be inaccurate. This may be referred to as an ABA lot sequence problem, or fast lost transition problem.

The present embodiment provides a technique for determining when fast lot transitions occur. This may be used to improve the accuracy of a reticle heating model.

According to the present embodiment, the handling of a reticle is tracked and used to generate reticle handling data. The reticle handling data comprises data on each location that the reticle has been in, as well as the time that the reticle was in each location. A determination on whether a fast lot transition has occurred is made in dependence on the reticle handling data and the known thermal properties of the reticle. A decision on how to configure the reticle heating model may then be made in dependence on whether a fast lot transition has occurred.

When a reticle is first loaded onto a reticle stage, the reticle heating model is initialized based on the assumption that the reticle is in a cold state. The cold state is the state of a reticle that has been appropriately conditioned by an IRL. The initialization of the reticle heating model may comprise setting reference data based on the on the first reticle alignment measurements of the substrates in the lot. The reference data may comprise, for example, the nominal reference state 1104 as described for the first embodiment. All of the states of the model may be initialized to zero, or other default values for when the reticle in its cold state.

As the first lot of substrates is processed, the states of the reticle heating model are updated to model the heating and resulting deformation of the reticle that has occurred.

After the first lot of substrates has been processed, a lot transition process may occur. All of the states of the reticle heating model at the end of the processing of the first lot of substrates are saved. Lithographic processes may then be performed with a different reticle, or no lithographic process may be performed.

For each reticle that may be used in the performed lithographic processes, reticle handling data may be generated. The reticle handling data may include data on how the reticle has been handled. The reticle handling data may include location data that describes the location where the reticle has been. The reticle handling data may include time data that describes how long the reticle has been at each location. The time data may also include data on when each of the lithographic processes performed with the reticle starts and ends, and when any other related processes start and end. The reticle handling data may include thermal data that describes the temperature at each location that the reticle has been. The reticle handling data may include data on the thermal properties of the reticle at each location. The reticle handling data in the present embodiment may be the same as the reticle handling data that is generated and used in the first embodiment.

According to the present embodiment, at the start of a process that re-uses each reticle, a determination is made of the condition of the reticle in dependence on the reticle handling data. In particular, an estimation of the temperature of the reticle may be made in dependence on the reticle handling data. If the estimated temperature is at, or above, a threshold value then a determination made be made that the reticle is in a hot state. A determination that the reticle is in a hot state may be equivalent to a determination that a fast lot transition has occurred. If the estimated temperature is below the threshold value, then a determination made be made that the reticle is in a cold state. A determination that the reticle is in a cold state may be equivalent to a determination that a fast lot transition has not occurred.

If the reticle is determined to be in a cold state, then the reticle heating model for the process that re-uses the reticle is re-initialized as for processes that are performed with a reticle that is in a cold state. The re-initialization of the reticle heating model may comprise setting reference data based on the on the first reticle alignment measurements of the substrates in the lot. The reference data may comprise, for example, the nominal reference state 1104 as described for the first embodiment. All of the states of the model may be initialized to zero, or other default values for when the reticle in a cold state.

If the reticle is alternatively determined to be in a hot state, then the reticle heating model for the process that re-uses the reticle is instead initialized with the earlier saved states of the reticle heating model at the end of the processing of the previous lot of substrates with the reticle. The model is thereby more appropriately initialized given the state of the reticle.

Advantageously, the reticle handling data allow fast lot transitions, such as with ABA scenarios, to be detected and provides a more appropriate initialization of the reticle heating model when the loaded reticle at the start of a process is in a hot state instead of a cold state. The techniques of the present embodiment may substantially reduce errors caused by the sensitivity of a reticle heating model to fast lot transitions. The techniques of embodiments may be applied computationally and do not reduce the throughput of a lithographic apparatus.

The present embodiment may be used with any reticle heating model. The present embodiment may be used in conjunction with first embodiment. In particular, the determination of the state of the reticle may be performed by the RRM 1202 that receives reticle handling data. Accordingly, the RRM 1202 may be a decision making module.

According to a third embodiment, a technique is provided for improving the accuracy of a reticle heating model when track hiccups occur.

A track hiccup may generally be defined as any timing abnormality that may occur when lithographic processes are performed. Examples of track hiccups include any event that results in an unintended delay to the load time of a substrate, a computing glitch that delays an operation being instructed, as well as any of a number of other unscheduled events that may occur.

The same reticle is used whilst lithographic processes are performed on a plurality of substrates in a lot. A track hiccup may occur during the processing of the lot. Known reticle heating models do not account for track hiccups. The occurrence of track hiccups are thereby a source of inaccuracies in the reticle heating model to the extent that the effect of the hiccup on the actual thermal state of the reticle is not modelled.

The present embodiment provides a technique for detecting both when a track hiccup has occurred and also determining if it is appropriate to re-initialize the reticle heating model in response to a track hiccup occurring. This may be used to improve the accuracy of a reticle heating model.

According to the present embodiment, when the reticle is loaded onto and remains clamped to a reticle stage, the processes with the reticle are tracked and used to generate reticle process data. The reticle process data comprises timing data on the performed exposure processes with the reticle as well as any other processes with the reticle whilst the reticle is clamped to the stage. A reticle heating model may be configured in dependence on the reticle process data. In particular, the occurrence and effect of a track hiccup may be determined in dependence on the reticle process data and known thermal properties of the reticle. The reticle heating model may then be configured in dependence on whether the track hiccup has had a substantial effect on the thermal properties of a reticle.

The present embodiment is described in more detail below.

When a reticle is first loaded onto a reticle stage, the reticle heating model may be initialized based on the assumption that the reticle is in a cold state. The cold state is the state of a reticle that has been appropriately conditioned by an IRL. The initialization of the reticle heating model may comprise setting reference data based on the on the first reticle alignment measurement performed on the first substrate in a lot. The reference data may comprise, for example, the nominal reference state 1104 as described for the first embodiment. All of the states of the reticle heating model may be initialized to zero, or other default values for when the reticle in a cold state.

As the first lot of substrates is processed, the state of the reticle heating model is updated to model the heating and resulting deformation of the reticle that has occurred.

Reticle process data is generated that comprises timing data on the performed exposure processes using the reticle, data on the dose of each exposure process, and data on any other processes that affect the properties of the reticle whilst the reticle remains clamped to the reticle stage. The reticle process data may be monitored and used to determine when a track hiccup has occurred. For example, a track hiccup may be determined to have occurred when an exposure process has not been performed within an expected time window for the exposure process. The determination that a track hiccup has occurred may also be made in dependence on other parts of the overall lithographic system. For example, the determination that a track hiccup has occurred may be made in dependence on the operation of the substrate handler.

When a determination is made that a track hiccup has occurred, the effect of the track hiccup on the reticle is determined. The time duration of the track hiccup may be known from the reticle process data. The thermal properties of the reticle may also be known. The reticle process data and known thermal properties of the reticle may be used to determine if the time duration of the track hiccup was sufficiently long for the temperature of the reticle to have substantially changed. In particular, a temperature change of the reticle may be estimated. A long track hiccup may be determined to have occurred when the temperature change is at, or above, a threshold value. A short track hiccup may be determined to have occurred when the temperature change is below the threshold value.

The use of the reticle, that has remained clamped to the stage, is resumed soon after the track hiccup has ended. The reticle heating model for the reticle is then configured in dependence on whether the track hiccup was determined to be a short track hiccup or a long track hiccup.

When a determination is made that the track hiccup was a short track hiccup, the reticle heating model is configured based on the state of the heating model before the track hiccup occurred. That is to say, the reticle heating model may not be substantially reconfigured and the reticle heating model may be operated as if no track hiccup had occurred.

When a determination is made that the track hiccup was a long track hiccup, the reticle heating model may be re-configured as if the reticle is an a cold state. That is to say, the reticle heating model may be re-configured to the same state as that used to initialize the reticle heating model when the reticle was first loaded onto the reticle stage. All of the states of the reticle heating model may be initialized to zero, or other default values for when the reticle in its cold state.

Advantageously, the present embodiment provides a more appropriate configuration of the reticle heating model when a track hiccup occurs. The techniques of the present embodiment may substantially reduce errors caused by the sensitivity of a reticle heating model to reticle temperature changes due to track hiccups. The techniques of embodiments may be applied computationally and do not reduce the throughput of a lithographic apparatus.

The present embodiment may be used with any reticle heating model. The present embodiment may be used in conjunction with all of the other embodiments described throughout the present document. In particular, the determination of whether a long or short track hiccup has occurred may be performed by the RRM 1202. Accordingly, the RRM 1202 may be a decision making module. The RRM 1202 may generate the reticle processing data, or receive the reticle processing data from another source. The known thermal properties of the reticle may be stored in the RRM 1202 or provided to the RRM 1202 from an external database.

According to a fourth embodiment a new technique is provided for determining and compensating for the effect of a clamping force. The fourth embodiment may be used in conjunction with the reticle heating model of the first embodiment and/or the techniques of any of the other embodiments described throughout the present document.

As described earlier, a reticle is clamped to a reticle stage 200. A problem that may occur is that the clamping force that holds the reticle may vary over time. This may be caused by, for example, locked in frictional stresses between the reticle and the reticle stage 200. A substantial variation of the clamping force may occur over a period of about 4 to 8 hours and, if not compensated for, increase the overlay error by about 2 nm.

It is known to compensate for the distortion caused by the clamping force variation by using RA measurements of edge marks and including the measurement data in a reticle heating model. However, this reduces the productivity by about 7 substrates per hour. Inaccuracies in each edge mark measurement also decrease the accuracy of the reticle heating model. The edge mark measurements also degrade the performance of the resist coating of a substrate W.

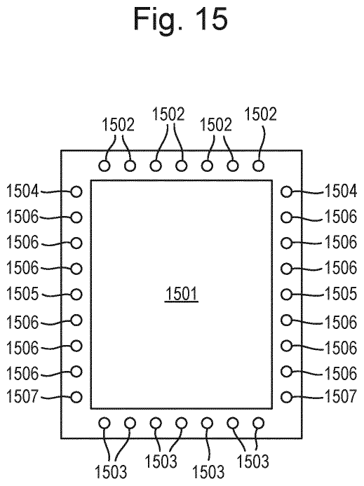

FIG. 15 shows a reticle 1501. The reticle 1501 is surrounded by horizontally aligned and vertically aligned edge markers 1502, 1503, 1504, 1505, 1506, 1507. The horizontally aligned edge markers 1502, 1503 include upper horizontal edge markers 1502 and lower horizontal edge markers 1503. The vertically aligned edge markers 1504, 1505, 1506, 1507 include central vertical edge markers 1505, upper vertical edge markers 1504, lower vertical edge markers 1507, and non-central vertical edge markers 1506.

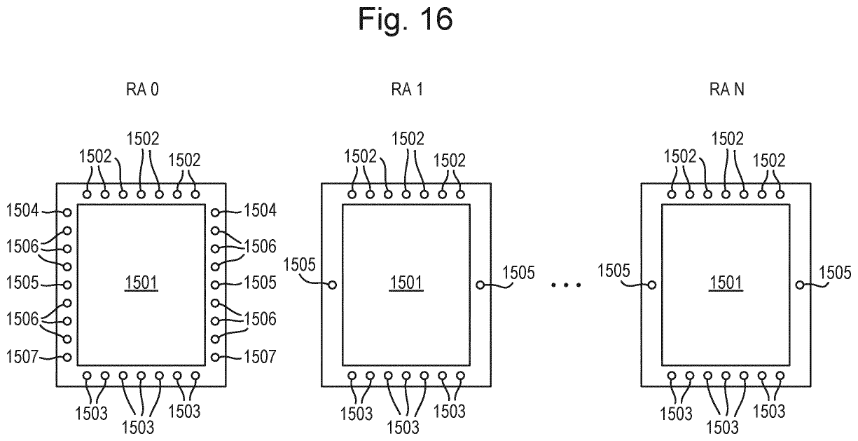

FIG. 16 shows how RA measurements are obtained for processes that are performed on a lot of substrates according to known techniques. For the first substrate in the lot, as shown by RA 0, RA measurements are obtained from all of the horizontally aligned and vertically aligned edge markers 1502, 1503, 1504, 1505, 1506, 1507. For each subsequent substrate in the lot, as shown by RA 1 to RA N, RA measurements are obtained from all of the horizontally aligned edge markers 1502, 1503 and at least the central vertical edge markers 1505.

The RA measurements for each substrate may be provided to a reticle heating model and used to determine the overall deformation shape of the reticle. In particular, the measurements from the central vertical edge markers 1505 are used to determine the deformation caused by clamping effects for each substrate.

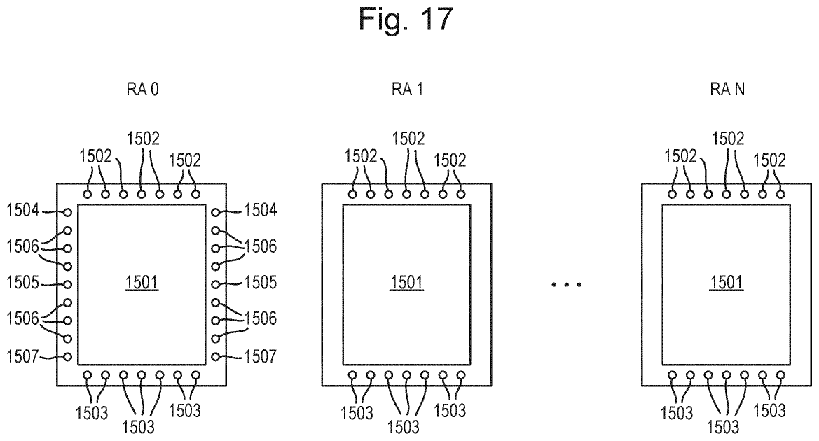

FIG. 17 shows the alternative technique for obtaining RA measurements for processes that are performed on a lot of substrates according to the present embodiment. For the first substrate in the lot, as shown by RA 0, RA measurements may be obtained from some, or all, of the horizontally aligned and vertically aligned edge markers 1502, 1503, 1504, 1505, 1506, 1507. For each subsequent substrate in the lot, as shown by RA 1 to RA N, RA measurements are obtained from some, or all, of the horizontally aligned edge markers 1502, 1503 only. The central vertical edge markers 1505 are therefore only measured for the first substrate and they are not measured for the subsequent substrates.

The RA measurements for the first substrate may be provided to a reticle heating model and used to determine the overall deformation shape of the reticle, including the effects of the shape of, and clamping to, the reticle stage 200. The same modelled deformation of the clamping effects is then used for the rest of the substrates in the lot. It is appropriate to use the same model of the clamping effects for each substrate in a lot because the time required to process a lot of substrates is typically 5 to 6 minutes, whereas clamping effects typically change over a period of 4 to 8 hours. The clamping effects therefore remain substantially unchanged as a lot of substrates is processed.

The RA measurements may also be used to separately determine the deformation caused by the clamping effects and the reticle induced deformation, such as due to reticle heating. The system drifts caused by clamping effects may then be determined and included used in calibrations to improve the accuracy of the modelled deformations.

Advantageously, the present embodiment increases the processing rate of substrates because less RA measurements are required. In addition, the present embodiment avoids the degrading of a resist that occurs when central vertical edge markers 1505 are measured for every substrate of a lot.

The RA measurements obtained in the present embodiment may be used by a reticle deformation model to determine the deformation caused by clamping effects. Process corrections may then be determined in dependence on the determined deformation for at least partially compensating for the deformation.

Embodiments include the reticle deformation model comprising a reticle heating model. In particular, the RA measurements obtained in the present embodiment may be used by the earlier described reticle heating model according to any of the other embodiments described herein. The RA measurements of the first substrate in a lot may be used to initialize the reticle heating model.

According to a fifth embodiment a new technique is provided for determining the deformation of the reticle shape that is caused by the clamping of the reticle by a reticle clamp. The determined deformation may then be at least partially compensated for.

As described earlier, a reticle is secured a reticle to a reticle stage 200 by a reticle clamp. The clamping force that is applied to the reticle by a reticle clamp may deform the shape of the reticle. The distribution of the clamping force, and the resulting deformation of the reticle shape, may be dependent on the shape of the clamping surface.

The reticle deformation caused by a static clamping force may be determined once and then compensated for. However, a problem that may occur is that the clamping force that holds the reticle is not static. That is to say, the clamping force may vary over time and the resulting deformation of the reticle shape may thereby vary over time. The time variation of the clamping force may be caused by, for example, locked in frictional stresses between the reticle and the reticle stage 200. A substantial variation of the clamping force may occur over a period of about 4 to 8 hours and, if not compensated for, increase the overlay error by about 2 nm.

Due to the time variation of the reticle deformation caused by the clamping force, known techniques frequently measure the overall reticle deformation so that the reticle deformation may be compensated for. In particular, known techniques obtain RA measurements and edge mark measurements of the reticle for each substrate that is being processed with the reticle. The RA measurements and edge mark measurements are then used to model the deformation of each substrate. Process corrections are then be applied to compensate for the determined deformation.

A problem with known techniques is that the time required to obtain the RA measurements and edge mark measurements reduces overall productivity of a lithographic system. Any inaccuracies in the each edge mark measurements are also a source of error. Obtaining edge mark measurements also degrades the performance of the resist coating of a substrate W.

In the fourth embodiment, a clamping-induced deformation is determined and provided to a reticle heating model. The reticle heating model determines the total reticle deformation in dependence on the determined clamping-induced deformation. The modelled total deformation may then be provided to a deformation based reticle heating controller.

The present embodiment provides a new technique for determining the clamping-induced deformation. In contrast to the techniques in the fourth embodiment, the determined clamping-induced deformation may be provided directly to a deformation based reticle heating controller. The determined clamping-induced deformation may not be provided to a reticle heating model, or may be both directly provided to a deformation based reticle heating controller and also to a reticle heating model.

In the present embodiment, the deformation of the reticle that is caused by the clamping force is determined in a way that does not require edge mark measurements for each substrate. The overall deformation of a reticle may be modelled as a combination of contributions to the overall deformation from different deformation modes. The present embodiment uses one or more previous measurements to determine the deformation modes that are caused by the clamping force. The determined deformation modes may be used to determine the reticle deformation caused by the clamping force, and to determine appropriate process corrections to at least partially compensate for the resulting reticle deformation. Advantageously, the present embodiment increases throughput because fewer edge measurements are required. Other problems experienced by known techniques may also be avoided, or reduced.

When a lithographic process is performed for forming features on a substrate, the shape of the reticle may be deformed by both heating effects and also the clamping force applied by the reticle clamp. However, the reticle heating effects are not substantially experienced when the reticle is appropriately conditioned and first loaded onto the reticle stage. That is to say, the reticle heating effects are not substantially experienced with the first use of a reticle that is in a cold state. When there are substantially no deformations due to reticle heating effects, the reticle clamping force and the inherent deformation resulting from the cold state of the reticle may be the substantial causes of the overall reticle deformation.

The effect of the overall reticle deformation that occurs may be measured from an inspection of the formed features on a substrate. In particular, it is known for the features formed on a substrate to be inspected by a metrology apparatus. The metrology apparatus may be used to determine one or more performance metrics of the lithographic processes performed on the substrate, such as on product overlay error and edge placement error.

According to the present embodiment, a metrology apparatus is used to determine one or more performance metrics when a reticle that is in a cold state is used. The substantial contribution to the reticle deformation measured by the one or more performance metrics is therefore the reticle deformation caused by the clamping force as well as the inherent deformation resulting from the cold state of the reticle. The deformation modes of the overall reticle deformation may be determined in dependence on the one or more performance metrics. The deformation modes may be determined by a number of known techniques, such as PCA analysis, a singular value decomposition and/or other techniques that may be performed by an algorithm.

The clamping-induced deformation modes may be determined in dependence on the determined deformation modes from the one or more performance metrics as well as predetermined knowledge of the inherent deformation modes present in the cold state of the reticle. The inherent deformation modes present in the cold state of the reticle may be obtained from a library. The inherent deformation modes present in the cold state of the reticle may comprise data on the expected shape and/or deformation of the reticle when the reticle is not clamped and the reticle has been appropriately temperature conditioned so that it is in a cold state.

The determination of the clamping-induced deformation allows the overall deformation resulting from the use of a reticle in a cold state to be predicted before lithographic processes are performed with the reticle. The overall deformation may be predicted in dependence on a previously determined clamping-induced deformation and knowledge of cold state of reticle that is about to be used. Process corrections for at least partially compensating for the predicted overall deformation may then be made. The determination and application of the process corrections may be performed inline.

The clamping-induced deformation modes may be determined in dependence on measurements of a plurality of reticles with each reticle being in a cold state. In particular, when a plurality of lots of substrates are processed, the first use of the reticle in each lot may be the use of a reticle that is in a cold state. For each use of a reticle in a cold state, the above techniques may be used to determine the clamping-induced deformation. The used prediction of the clamping-induced deformation may be based on a plurality of the previously determined clamping-induced deformations.

The clamping-induced deformation modes, that may be determined as described above, may be used to calibrate a reticle deformation model so as to include the effect of the reticle clamp. The reticle deformation model may additionally determine the overall deformation of a reticle in dependence on the expected deformation modes of the reticle in its cold state and/or reticle heating effects.

According to the present embodiment, when a lot of substrates is processed, the determination of the reticle deformation due to clamping effects is based on the clamping-induced deformation modes that may be obtained as described above. The clamping-induced deformation is thereby calculated in dependence on one or more previously used reticles in a cold state. It is appropriate for the same recently determined clamping-induced deformation to be used for an entire lot of substrates because the processing time of a lot may be a few minutes, whereas a substantial variation of the clamping force may require 4 to 8 hours.

The determined overall deformation of the reticle, which may include all of a determination of heating induced reticle deformation, the expected deformation of a reticle in a cold state, and a determination of the deformation caused by the clamping force, may then be used to determine process corrections for at least partially compensating for the overall deformation of the reticle.

Advantageously, the present embodiment provides a model with a mode based determination of the effect of the clamping of the reticle. The techniques of embodiments may be applied in-line to predict variations in the deformation of a reticle. Embodiments avoid the requirement of in-line edge mark measurements of each substrate in a lot. Due to the model being mode based, the modal-deformation shapes may be tuned based on the specific properties of a reticle and/or reticle clamp, and/or how the reticle and/or reticle clamp are used. For example, the modal deformation model may be applied to different reticle layouts. The density of the deformation measurement may also be varied, as may be appropriate for tuning the determination of the parameters for correcting the deformation.

The present embodiment also allows variation, and drift, of a clamping force to be measured and monitored. This provides useful performance information about a reticle clamp.

The techniques of the present embodiment may be used in combination with the techniques of one or more of the previous embodiments. In particular, the present embodiment may be used together with the techniques of the fourth embodiment.

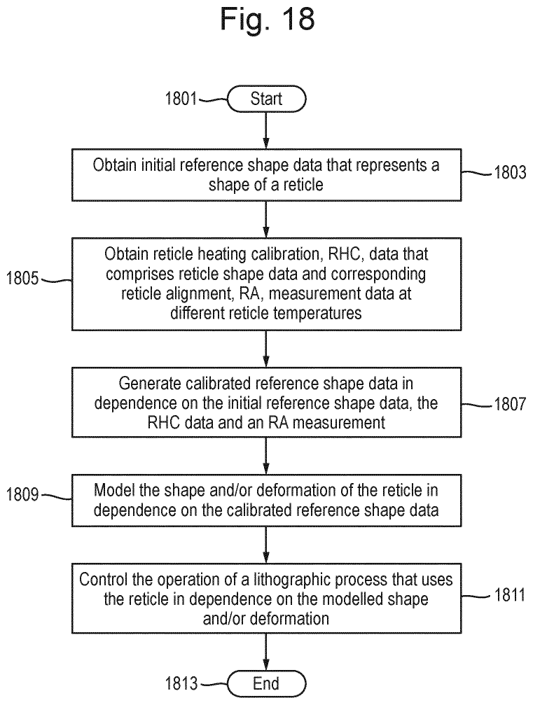

FIG. 18 is a flowchart of a method according to the first embodiment.

In step 1801, the method starts.

In step 1803, initial reference shape data that represents a shape of a reticle is obtained.

In step 1805, reticle heating calibration, RHC, data that comprises reticle shape data and corresponding reticle alignment, RA, measurement data is obtained at different reticle temperatures.

In step 1807, calibrated reference shape data is generated in dependence on the initial reference shape data, the RHC data and an RA measurement.

In step 1809, the shape and/or deformation of the reticle is modelled in dependence on the calibrated reference shape data.

In step 1811, the operation of a lithographic process that uses the reticle is controlled in dependence on the modelled shape and/or deformation.

In step 1813, the method ends.

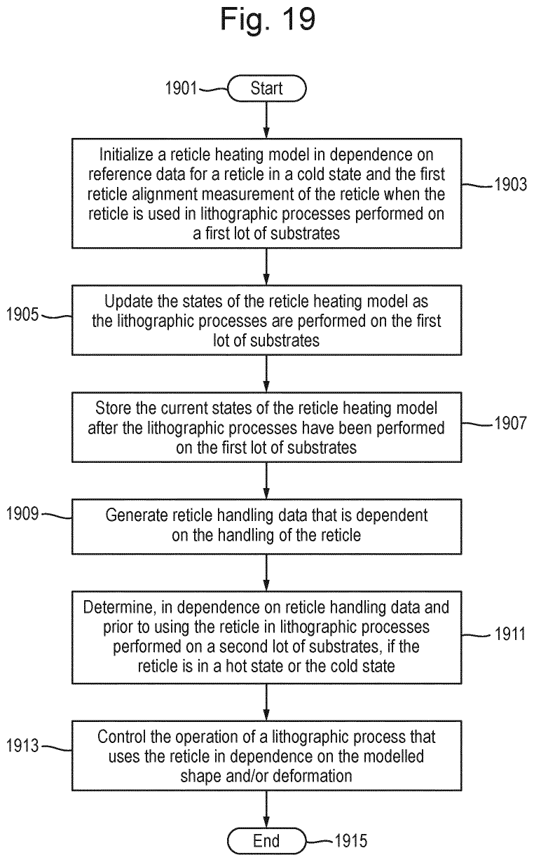

FIG. 19 is a flowchart of a method according to the second embodiment.

In step 1901, the method begins.

In step 1903, a reticle heating model is initialized in dependence on reference data for a reticle in a cold state and the first reticle alignment measurement of the reticle when the reticle is used in lithographic processes performed on a first lot of substrates.

In step 1905, the states of the reticle heating model are updated as the lithographic processes are performed on the first lot of substrates.

In step 1907, the current states of the reticle heating model are stored after the lithographic processes have been performed on the first lot of substrates.

In step 1909, reticle handling data is generated that is dependent on the handling of the reticle.

In step 1911, a determination is made, in dependence on reticle handling data and prior to using the reticle in lithographic processes performed on a second lot of substrates, if the reticle is in a hot state or the cold state.

In step 1913, the operation of a lithographic process that uses the reticle is controlled in dependence on the modelled shape and/or deformation.

In step 1915, the method ends.

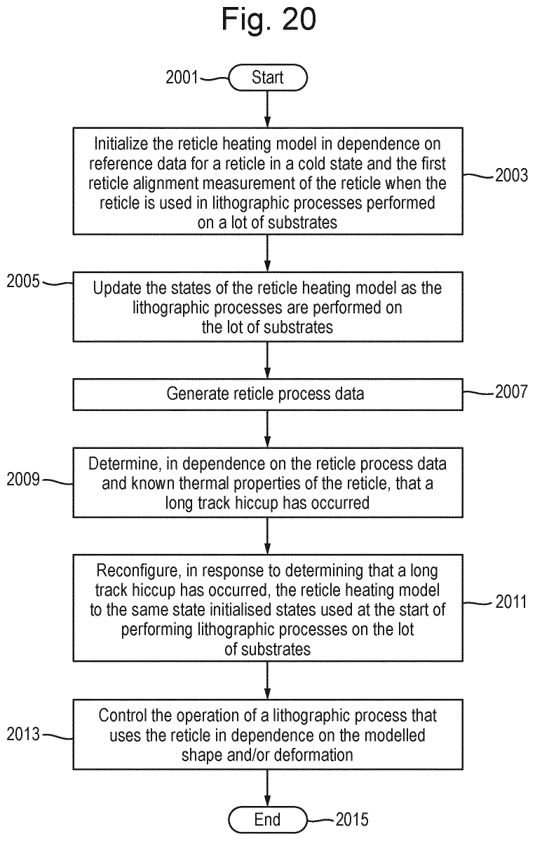

FIG. 20 is a flowchart of a method according to the third embodiment.

In step 2001, the method starts.

In step 2003, the reticle heating model is initialized in dependence on reference data for a reticle in a cold state and the first reticle alignment measurement of the reticle when the reticle is used in lithographic processes performed on a lot of substrates.

In step 2005, the states of the reticle heating model are updated as the lithographic processes are performed on the lot of substrates.

In step 2007, reticle process data is generated.

In step 2009, a determination is made, in dependence on the reticle process data and known thermal properties of the reticle, that a long track hiccup has occurred.

In step 2011, in response to determining that a long track hiccup has occurred, the reticle heating model is reconfigured to the same state initialized states used at the start of performing lithographic processes on the lot of substrates.

In step 2013, the operation of a lithographic process that uses the reticle is controlled in dependence on the modelled shape and/or deformation.

In step 2015, the method ends.

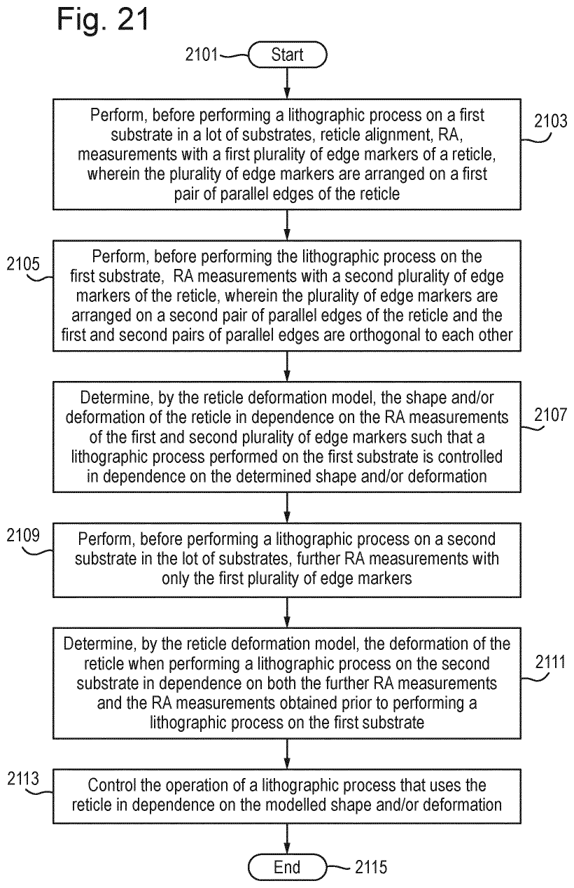

FIG. 21 is a flowchart of a method according to the fourth embodiment.

In step 2101, the method starts.

In step 2103, before performing a lithographic process on a first substrate in a lot of substrates, reticle alignment, RA, measurements are performed with a first plurality of edge markers of the reticle, wherein the plurality of edge markers are arranged on a first pair of parallel edges of the reticle.

In step 2105, before performing the lithographic process on the first substrate, RA measurements are performed with a second plurality of edge markers of the reticle, wherein the plurality of edge markers are arranged on a second pair of parallel edges of the reticle and the first and second pairs of parallel edges are orthogonal to each other.

In step 2107, a determination is made, by the reticle deformation model, of the shape and/or deformation of the reticle in dependence on the RA measurements of the first and second plurality of edge markers such that a lithographic process performed on the first substrate is controlled in dependence on the determined shape and/or deformation.

In step 2109, before performing a lithographic process on a second substrate in the lot of substrates, further RA measurements are performed with only the first plurality of edge markers.

In step 2111, a determination is made, by the reticle deformation model, of the deformation of the reticle when performing a lithographic process on the second substrate in dependence on both the further RA measurements and the RA measurements obtained prior to performing a lithographic process on the first substrate.

In step 2113, the operation of a lithographic process that uses the reticle is controlled in dependence on the modelled shape and/or deformation.

In step 2115, the method ends.

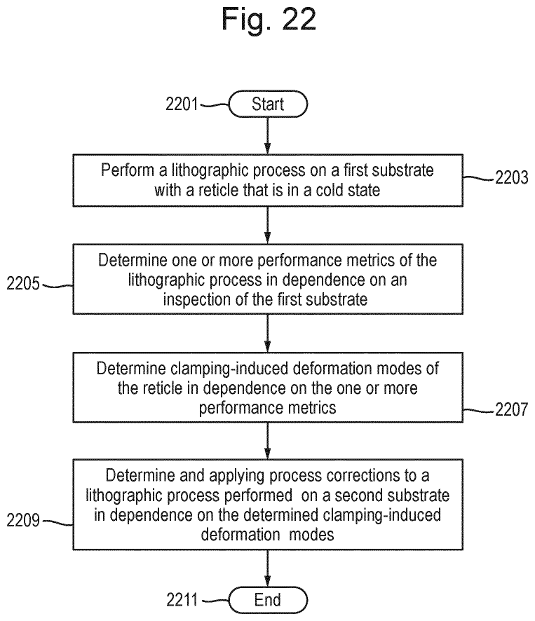

FIG. 22 is a flowchart of a method according to the fifth embodiment.

In step 2201, the method starts.

In step 2203, a lithographic process is performed on a first substrate with a reticle that is in a cold state.

In step 2205, one or more performance metrics of the lithographic process are determined in dependence on an inspection of the first substrate.

In step 2207, clamping-induced deformation modes of the reticle are determined in dependence on the one or more performance metrics.

In step 2209, process corrections are determined and applied to a lithographic process performed on a second substrate in dependence on the determined clamping-induced deformation modes.

In step 2211, the method ends.

Embodiments include a number of modifications and variations to the above-described techniques.

In all of the above-described first to fifth embodiments, the reticle may be the reticle 300 as described with reference to FIGS. 1 to 10. Embodiments also include a different type of reticle being used.

In all of the above-described first to fifth embodiments, the reticle clamp may be the clamp 250 as described with reference to FIGS. 1 to 10. Embodiments also include a different type of reticle clamp being used.

In all of the above-described first to fifth embodiments, the reticle stage may be the reticle stage 200 as described with reference to FIGS. 1 to 10. Embodiments also include a different type of reticle stage being used.

In all of the above-described first to fifth embodiments, the reticle handler may be the reticle handler 402 as described with reference to FIGS. 1 to 10. Embodiments also include a different type of reticle handler being used.

In all of the above-described first to fifth embodiments, the substrate may be the substrate W as described with reference to FIGS. 1 to 10. Embodiments also include a different type of substrate being used.

In all of the above-described first to fifth embodiments, the lithographic system may be the lithographic system as described with reference to FIGS. 1 to 10. Embodiments also include a different type of lithographic system being used.

In the first embodiment, the RRM 1202 and the RM 1201 are separate modules. Embodiments also include a single module performing the tasks of both the RRM 1202 and the RM 1201.

Embodiments may be used with any type of lithographic system. For example, the lithographic system may be an EUV system or a DUV system. The lithographic system may be any design and is not restricted to the specific types of system shown in FIGS. 1 to 2B.

In all embodiments, the described determinations may be performed by algorithms implemented in a computer system. The computer system may also determine and apply process corrections for controlling the operation of a lithographic system in dependence on the determinations.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track unit (a tool that typically applies a layer of resist to a substrate and develops the exposed resist), a metrology unit and/or an inspection unit. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of aspects in the context of optical lithography, it will be appreciated that aspects may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself may be patterned and materials added on top of it may also be patterned, or may remain without patterning.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

Although specific reference may be made in this text to the use of the apparatus and/or system in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific aspects have been described above, it will be appreciated that the aspects may be practiced otherwise than as described. The description is not intended to limit the scope of the claims.

It is to be appreciated that the Detailed Description section, and not the Summary and Abstract sections, is intended to be used to interpret the claims. The Summary and Abstract sections may set forth one or more but not all exemplary aspects as contemplated by the inventor(s), and thus, are not intended to limit the aspects and the appended claims in any way.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

Embodiments include the following first set of numbered clauses
1. A computer system configured to:
model the shape and/or deformation of a reticle; and control the operation of a lithographic process that uses the reticle in dependence on the modelled shape and/or deformation;
wherein to model the shape and/or deformation of the reticle, the computer system is configured to: obtain initial reference shape data that represents a shape of a reticle;
obtain reticle heating calibration, RHC, data that comprises reticle shape data and corresponding reticle alignment, RA, measurement data at different reticle temperatures;
generate calibrated reference shape data in dependence on the initial reference shape data, the RHC data and an RA measurement; and
model the shape and/or deformation of the reticle in dependence on the calibrated reference shape data.
2. The computer system according to clause A1, wherein, to generate the RHC data, the computer system is configured to:
   obtain a first data set that comprises reticle shape data and corresponding RA measurement data at different reticle temperatures as the temperature of the reticle is reduced during a first time period;
   obtain a second data set that comprises reticle shape data and corresponding RA measurement data at different reticle temperatures as the temperature of the reticle is increased during a second time period, wherein the second time period is subsequent to the first time period and a process for reducing the stress in the reticle is performed between the first time period and the second time period; and
generate the RHC data in dependence on the first data set and the second data set.
3. The computer system according to clause A2, wherein the computer system is configured to determine the RHC data in dependence on a comparison of the first data set and the second data set.
4. The computer system according to any of clauses A1 to A3, wherein the calibrated reference shape data is dependent on a determination of the shape of the reticle when the reticle is in a cold state.
5. The computer system according to any of clauses A1 to A4, wherein the calibrated reference shape data is dependent on a determination of the shape of the reticle when the reticle has heated to its current temperature from the cold state of the reticle.
6. The computer system according to any of clauses A1 to A5, wherein the calibrated reference shape data is dependent on a determination of a stress reduced state of the reticle.
7. A method comprising:
modelling the shape and/or deformation of a reticle; and
controlling the operation of a lithographic process that uses the reticle in dependence on the modelled shape and/or deformation;
wherein modelling the shape and/or deformation of the reticle comprises:
obtaining initial reference shape data that represents a shape of a reticle;
obtaining reticle heating calibration, RHC, data that comprises reticle shape data and corresponding reticle alignment, RA, measurement data at different reticle temperatures;
generating calibrated reference shape data in dependence on the initial reference shape data, the RHC data and an RA measurement; and
modelling the shape and/or deformation of the reticle in dependence on the calibrated reference shape data.
8. The method according to clause A7, further comprising generating the RHC data by:
   obtaining a first data set that comprises reticle shape data and corresponding RA measurement data at different reticle temperatures as the temperature of the reticle is reduced during a first time period;
   obtaining a second data set that comprises reticle shape data and corresponding RA measurement data at different reticle temperatures as the temperature of the reticle is increased during a second time period, wherein the second time period is subsequent to the first time period and a process for reducing the stress in the reticle is performed between the first time period and the second time period; and
generating the RHC data in dependence on the first data set and the second data set.
9. The method according to clause A8, wherein the RHC data is determined in dependence on a comparison of the first data set and the second data set.
10. The method according to any of clauses A7 to A9, wherein the calibrated reference shape data is dependent on a determination of the shape of the reticle when the reticle is in a cold state.
11. The method according to any of clauses A7 to A10, wherein the calibrated reference shape data is dependent on a determination of the shape of the reticle when the reticle has heated to its current temperature from the cold state of the reticle.
12. The method according to any of clauses A7 to A11, wherein the calibrated reference shape data is dependent on a determination of a stress reduced state of the reticle.
13. A system comprising:
a computer system according to any of clauses A1 to A6; and a lithographic apparatus;
wherein the computer system is configured to control the operation of lithographic apparatus.
14. A device manufacturing method using a lithographic process, the device manufacturing method comprising the method according to any of clauses A7 to A12.
15. A non-transitory computer readable medium program comprising computer readable instructions configured to cause a processor to control a lithographic apparatus according to the method of any of clauses A7 to A12.

Embodiments include the following second set of numbered clauses:
1. A computer system configured to use a reticle heating model to determine the shape and/or deformation of a reticle; and
   control the operation of a lithographic process that uses the reticle in dependence on the modelled shape and/or deformation;
   wherein the computer system is configured to:
initialize the reticle heating model in dependence on reference data for a reticle in a cold state and the first reticle alignment measurement of the reticle when the reticle is used in lithographic processes performed on a first lot of substrates;
update the states of the reticle heating model as the lithographic processes are performed on the first lot of substrates;
store the current states of the reticle heating model after the lithographic processes have been performed on the first lot of substrates;
generate reticle handling data that is dependent on the handling of the reticle;
determine, in dependence on reticle handling data and prior to using the reticle in lithographic processes performed on a second lot of substrates, if the reticle is in a hot state or the cold state;
if the reticle is determined to be in the hot state, configure the starting state for the reticle heating model for the lithographic processes performed on the second lot of substrates in dependence on the stored states of the reticle heating model; and
if the reticle is determined to be in the cold state, re-initialize the reticle heating model in dependence on reference data for the reticle in a cold state and the first reticle alignment measurement of the reticle when processing the second lot of substrates.
2. The computer system according to clause B1, wherein the computer system is further configured to determine the reticle temperature in dependence on the reticle handling data.
3. The computer system according to clause B2, wherein the computer system is configured to determine that the reticle is in the hot state if the determined reticle temperature is above a threshold value; and
the computer system is configured to determine that the reticle is in a cold state if the determined reticle temperature is below a threshold value.
4. The computer system according to any of clauses B1 to B3, wherein the reticle handling data includes one or more of:
location data that describes the location where the reticle is and has been;
time data that describes how long the reticle has been at each location and/or when each of the lithographic processes performed with the reticle starts and ends;
thermal data that describes the temperature at each location that the reticle has been; and data on the thermal properties of the reticle at each location.
5. The computer system according to any of clauses B1 to B4, wherein first lot of substrates comprises the same substrates as the second lot of substrates.
6. A method comprising:
   using a reticle heating model to determine the shape and/or deformation of a reticle; and
   controlling the operation of a lithographic process that uses the reticle in dependence on the modelled shape and/or deformation;
   wherein the method comprises:
initializing the reticle heating model in dependence on reference data for a reticle in a cold state and the first reticle alignment measurement of the reticle when the reticle is used in lithographic processes performed on a first lot of substrates;
updating the states of the reticle heating model as the lithographic processes are performed on the first lot of substrates;
storing the current states of the reticle heating model after the lithographic processes have been performed on the first lot of substrates;
generating reticle handling data that is dependent on the handling of the reticle;
determining, in dependence on reticle handling data and prior to using the reticle in lithographic processes performed on a second lot of substrates, if the reticle is in a hot state or the cold state;
if the reticle is determined to be in the hot state, configuring the starting state for the reticle heating model for the lithographic processes performed on the second lot of substrates in dependence on the stored states of the reticle heating model; and
if the reticle is determined to be in the cold state, re-initializing the reticle heating model in dependence on reference data for the reticle in a cold state and the first reticle alignment measurement of the reticle when processing the second lot of substrates.
7. The method according to clause B6, further comprising determining the reticle temperature in dependence on the reticle handling data.
8. The method according to clause B7, wherein the reticle is determined to be in the hot state if the determined reticle temperature is above a threshold value; and
the reticle is determined to be in a cold state if the determined reticle temperature is below a threshold value.
9. The method according to any of clauses B6 to B8, wherein the reticle handling data includes one or more of:
location data that describes the location where the reticle is and has been;
time data that describes how long the reticle has been at each location and/or when each of the lithographic processes performed with the reticle starts and ends;
thermal data that describes the temperature at each location that the reticle has been; and data on the thermal properties of the reticle at each location.
10. The method according to any of clauses B6 to B9, wherein first lot of substrates comprises the same substrates as the second lot of substrates.
11. A system comprising:
a computer system according to any of clauses B1 to B5; and
a lithographic apparatus; wherein the computer system is configured to control the operation of lithographic apparatus.
12. A device manufacturing method using a lithographic process, the device manufacturing method comprising the method according to any of clauses B6 to B10.
13. A non-transitory computer readable medium program comprising computer readable instructions configured to cause a processor to control a lithographic apparatus according to the method of any of clauses B6 to B10.

Embodiments include the following third set of numbered clauses:
1. A computer system configured to:
   use a reticle heating model to determine the shape and/or deformation of a reticle; and
   control the operation of a lithographic process that uses the reticle in dependence on the modelled shape and/or deformation;
   wherein the computer system is configured to:
initialize the reticle heating model in dependence on reference data for a reticle in a cold state and the first reticle alignment measurement of the reticle when the reticle is used in lithographic processes performed on a lot of substrates;
update the states of the reticle heating model as the lithographic processes are performed on the lot of substrates;
generate reticle process data;
determine, in dependence on the reticle process data and known thermal properties of the reticle, that a long track hiccup has occurred; and
in response to determining that a long track hiccup has occurred, reconfigure the reticle heating model to the same state initialized states used at the start of performing lithographic processes on the lot of substrates.
2. The computer system according to clause C1, wherein the computer system is configured to: detect, in dependence on the reticle process data, if a track hiccup has occurred;
determine, in dependence on the reticle process data and known thermal properties of the reticle, that a short track hiccup has occurred; and
in response to determining that a short track hiccup has occurred, to continue to use the reticle heating model based on the states of the reticle heating model when the track hiccup was detected.
3. The computer system according to clause C2, wherein the computer system is configured to detect that a track hiccup has occurred in dependence on one or more of:
a determination that an exposure process has not been performed within an expected time window for the exposure process; and/or
a determination that an unscheduled change has occurred in the operation of part of the lithographic system used to perform lithographic process with the reticle.
4. The computer system according to any of clauses C1 to C3, wherein the computer system is configured to determine the temperature of the reticle in dependence on the reticle process data and known thermal properties of the reticle;
wherein the determination that a long track hiccup has occurred is dependent on the temperature change of the reticle caused by the track hiccup being greater than a threshold value.
5. The computer system according to clause C4 when dependent on clause C2, wherein the determination that a short track hiccup has occurred is dependent on the temperature change of the reticle caused by the track hiccup being less than a threshold value.
6. The computer system according to any of clauses C1 to C5, wherein the reticle process data includes one or more of:
timing data on the performed exposure processes using the reticle;
data on the dose of each exposure process; and
data on any processes that affect the properties of the reticle whilst the reticle remains clamped to the reticle stage.
7. The computer system according to any of clauses C1 to C6, wherein the reticle remains clamped to a reticle stage when a track hiccup occurs.
8. A method comprising:
   using a reticle heating model to determine the shape and/or deformation of a reticle; and
   controlling the operation of a lithographic process that uses the reticle in dependence on the modelled shape and/or deformation;
   wherein the method comprises:
initializing the reticle heating model in dependence on reference data for a reticle in a cold state and the first reticle alignment measurement of the reticle when the reticle is used in lithographic processes performed on a lot of substrates;
updating the states of the reticle heating model as the lithographic processes are performed on the lot of substrates;
generating reticle process data;
determining, in dependence on the reticle process data and known thermal properties of the reticle, that a long track hiccup has occurred; and
in response to determining that a long track hiccup has occurred, reconfiguring the reticle heating model to the same state initialised states used at the start of performing lithographic processes on the lot of substrates.
9. The method according to clause C8, further comprising:
detecting, in dependence on the reticle process data, if a track hiccup has occurred;
determining, in dependence on the reticle process data and known thermal properties of the reticle, that a short track hiccup has occurred; and
in response to determining that a short track hiccup has occurred, continuing to use the reticle heating model based on the states of the reticle heating model when the track hiccup was detected.
10. The method according to clause C9, wherein detecting that a track hiccup has occurred comprises one or more of:
determining that an exposure process has not been performed within an expected time window for the exposure process; and/or
determining an unscheduled change has occurred in the operation of part of the lithographic system used to perform lithographic process with the reticle.
11. The method according to any of clauses C8 to C10, further comprising determining the temperature of the reticle in dependence on the reticle process data and known thermal properties of the reticle;
wherein the determination that a long track hiccup has occurred is dependent on the temperature change of the reticle caused by the track hiccup being greater than a threshold value.
12. The method according to clause C11 when dependent on clause C9, wherein the determination that a short track hiccup has occurred is dependent on the temperature change of the reticle caused by the track hiccup being less than a threshold value.
13. The method according to any of clauses C8 to C12, wherein the reticle process data includes one or more of:
timing data on the performed exposure processes using the reticle;
data on the dose of each exposure process; and
data on any processes that affect the properties of the reticle whilst the reticle remains clamped to the reticle stage.
14. The method according to any of clauses C8 to C13, wherein the reticle remains clamped to a reticle stage when a track hiccup occurs.
15. A system comprising:
a computer system according to any of clauses C1 to C7; and
a lithographic apparatus;
wherein the computer system is configured to control the operation of lithographic apparatus.
16. A device manufacturing method using a lithographic process, the device manufacturing method comprising the method according to any of clauses C8 to C13.
17. A non-transitory computer readable medium program comprising computer readable instructions configured to cause a processor to control a lithographic apparatus according to the method of any of clauses C8 to C13.

Embodiments include the following fourth set of numbered clauses:
1. A computer system configured to:
   use a reticle deformation model to determine the shape and/or deformation of a reticle; and
   control the operation of a lithographic process that uses the reticle in dependence on the modelled shape and/or deformation;
   wherein the computer system is configured to:
   perform, before performing a lithographic process on a first substrate in a lot of substrates, reticle alignment, RA, measurements with a first plurality of edge markers of the reticle, wherein the plurality of edge markers are arranged on a first pair of parallel edges of the reticle;
   perform, before performing the lithographic process on the first substrate, RA measurements with a second plurality of edge markers of the reticle, wherein the plurality of edge markers are arranged on a second pair of parallel edges of the reticle and the first and second pairs of parallel edges are orthogonal to each other;
determine, by the reticle deformation model, the shape and/or deformation of the reticle in dependence on the RA measurements of the first and second plurality of edge markers such that a lithographic process performed on the first substrate is controlled in dependence on the determined shape and/or deformation;
perform, before performing a lithographic process on a second substrate in the lot of substrates, further RA measurements with only the first plurality of edge markers; and
determine, by the reticle deformation model, the deformation of the reticle when performing a lithographic process on the second substrate in dependence on both the further RA measurements and the RA measurements obtained prior to performing a lithographic process on the first substrate.

2. The computer system according to clause D1, wherein the lot of substrates comprises more than two substrates and the computer system is configured to:
perform, between performing lithographic processes on two consecutive substrates in the lot of substrates, RA measurements with only the first plurality of edge markers; and
determine, by the reticle deformation model, the deformation of the reticle when performing a lithographic process on each substrate in dependence on both the most recently performed RA measurements and the RA measurements obtained prior to performing a lithographic process on the first substrate.
3. The computer system according to clause D1 or D2, wherein the reticle deformation model is configured to determine the clamping-induced reticle deformation before a lithographic process is performed on the first substrate; and
the same determined clamping-induced reticle deformation is used in all of the substrates of the lot.
4. The computer system according to any of clauses D1 to D3, wherein the computer system is configured to include the clamping-induced reticle deformation in the initial state of a reticle heating model.
5. A method comprising:
   using a reticle deformation model to determine the shape and/or deformation of a reticle; and
   controlling the operation of a lithographic process that uses the reticle in dependence on the modelled shape and/or deformation;
   wherein the method comprises:
   performing, before performing a lithographic process on a first substrate in a lot of substrates, reticle alignment, RA, measurements with a first plurality of edge markers of the reticle, wherein the plurality of edge markers are arranged on a first pair of parallel edges of a reticle;
   performing, before performing the lithographic process on the first substrate, RA measurements with a second plurality of edge markers of the reticle, wherein the plurality of edge markers are arranged on a second pair of parallel edges of a reticle and the first and second pairs of parallel edges are orthogonal to each other;
determining, by the reticle deformation model, the shape and/or deformation of the reticle in dependence on the RA measurements of the first and second plurality of edge markers such that a lithographic process performed on the first substrate is controlled in dependence on the determined shape and/or deformation;
performing, before performing a lithographic process on a second substrate in the lot of substrates, further RA measurements with only the first plurality of edge markers; and
determining, by the reticle deformation model, the deformation of the reticle when performing a lithographic process on the second substrate in dependence on both the further RA measurements and the RA measurements obtained prior to performing a lithographic process on the first substrate.
6. The method according to clause D5, wherein the lot of substrates comprises more than two substrates and the method further comprises:
performing, between performing lithographic processes on two consecutive substrates in the lot of substrates, RA measurements with only the first plurality of edge markers; and
determining, by the reticle deformation model, the deformation of the reticle when performing a lithographic process on each substrate in dependence on both the most recently performed RA measurements and the RA measurements obtained prior to performing a lithographic process on the first substrate.
7. The method according to clause D5 or D6, wherein the reticle deformation model determines the clamping-induced reticle deformation before a lithographic process is performed on the first substrate; and
the same determined clamping-induced reticle deformation is used in all of the substrates of the lot.
8. The method according to any of clauses D5 to D7, wherein the method comprises including the clamping-induced reticle deformation in the initial state of a reticle heating model.
9. A system comprising: a computer system according to any of clauses D1 to D4; and a lithographic apparatus;
wherein the computer system is configured to control the operation of lithographic apparatus.
10. A device manufacturing method using a lithographic process, the device manufacturing method comprising the method according to any of clauses D5 to D8.
11. A non-transitory computer readable medium program comprising computer readable instructions configured to cause a processor to control a lithographic apparatus according to the method of any of clauses D5 to D8.

Embodiments include the following fifth set of numbered clauses:
1. A computer system configured to:
   control a lithographic process performed on a first substrate with a reticle that is in a cold state;
   determine one or more performance metrics of the lithographic process in dependence on an inspection of the first substrate;
   determine clamping-induced deformation modes of the reticle in dependence on the one or more performance metrics; and
   determine and control the application of process corrections to a lithographic process performed on a second substrate in dependence on the determined clamping-induced deformation modes.
2. The computer system according to clause E1, wherein the one or more performance metrics are determined in dependence on measurements of the properties of features formed on the first substrate by the lithographic process.
3. The computer system according to clause E1 or E2, wherein the computer system is configured to determine the clamping-induced deformation modes by:
determining the deformation modes of the overall reticle deformation in dependence on the one or more performance metrics;
obtaining data on the expected deformation modes of the reticle in a cold state when the reticle is not clamped; and
determining the clamping-induced deformation modes in dependence on the determined deformation modes of the overall reticle deformation and the expected deformation modes of the reticle in a cold state when the reticle is not clamped.
4. The computer system according to any of clauses E1 to E3, wherein the first and second substrates are in different lots of substrates.
5. The computer system according to any of clauses E1 to E4, wherein the computer system is configured to determine clamping-induced deformation modes of a reticle in a cold state for each of a plurality of lots of substrates such that, for each lot of substrates, clamping-induced deformation modes of the used reticle are determined;
wherein the computer system is configured to determine and control the application of process corrections to a lithographic process in dependence on the plurality of determinations of clamping-induced deformation modes.
6. A method comprising:
   performing a lithographic process on a first substrate with a reticle that is in a cold state;
   determining one or more performance metrics of the lithographic process in dependence on an inspection of the first substrate;
   determining clamping-induced deformation modes of the reticle in dependence on the one or more performance metrics; and
   determining and applying process corrections to a lithographic process performed on a second substrate in dependence on the determined clamping-induced deformation modes.
7. The method according to clause E6, wherein the one or more performance metrics are determined in dependence on measurements of the properties of features formed on the first substrate by the lithographic process.
8. The method according to clause E6 or E7, wherein determining the clamping-induced deformation modes comprises:
determining the deformation modes of the overall reticle deformation in dependence on the one or more performance metrics;
obtaining data on the expected deformation modes of the reticle in a cold state when the reticle is not clamped; and
determining the clamping-induced deformation modes in dependence on the determined deformation modes of the overall reticle deformation and the expected deformation modes of the reticle in a cold state when the reticle is not clamped.
9. The method according to any of clauses E6 to E8, wherein the first and second substrates are in different lots of substrates.
10. The method according to any of clauses E6 to E9, further comprising performing the method with a reticle in a cold state for each of a plurality of lots of substrates such that, for each lot of substrates, clamping-induced deformation modes of the used reticle are determined;
wherein the applied process corrections to a lithographic process are determined in dependence on the plurality of clamping-induced determinations of deformation modes.
11. A system comprising:
a computer system according to any of clauses E1 to E5; and
a lithographic apparatus;
wherein the computer system is configured to control the operation of lithographic apparatus.
12. A device manufacturing method using a lithographic process, the device manufacturing method comprising the method according to any of clauses E6 to E10.
13. A non-transitory computer readable medium program comprising computer readable instructions configured to cause a processor to control a lithographic apparatus according to the method of any of clauses E6 to E10.

The breadth and scope of the aspects should not be limited by any of the above-described exemplary aspects, but should be defined only in accordance with the following claims and their equivalents.

1-13. (canceled)

14. A computer system configured to perform operations comprising:
controlling a lithographic process performed on a first substrate with a reticle that is in a cold state;
determining one or more performance metrics of the lithographic process in dependence on an inspection of the first substrate;
determining clamping-induced deformation modes of the reticle in dependence on the one or more performance metrics; and
determining and controlling application of process corrections to a lithographic process performed on a second substrate in dependence on the determined clamping-induced deformation modes.

15. The computer system according to claim 14, wherein the one or more performance metrics are determined in dependence on measurements of properties of features formed on the first substrate by the lithographic process.

16. The computer system according to claim 14, wherein the determining the clamping-induced deformation modes comprises:
determining the deformation modes of overall reticle deformation in dependence on the one or more performance metrics;
obtaining data on expected deformation modes of the reticle in a cold state when the reticle is not clamped; and
determining the clamping-induced deformation modes in dependence on the determined deformation modes of the overall reticle deformation and the expected deformation modes of the reticle in the cold state when the reticle is not clamped.

17. The computer system according to claim 14, wherein the first and second substrates are in different lots of substrates.

18. The computer system according to claim 14, wherein:
the determining the clamping-induced deformation modes of the reticle in the cold state for each of a plurality of lots of substrates such that, for each lot of substrates, clamping-induced deformation modes of the used reticle are determined;
the determining and controlling the application of the process corrections to the lithographic process is performed in dependence on the plurality of determinations of the clamping-induced deformation modes.

19. A method comprising:
performing a lithographic process on a first substrate with a reticle that is in a cold state;
determining one or more performance metrics of the lithographic process in dependence on an inspection of the first substrate;
determining clamping-induced deformation modes of the reticle in dependence on the one or more performance metrics; and
determining and applying process corrections to a lithographic process performed on a second substrate in dependence on the determined clamping-induced deformation modes.

20. The method according to claim 19, wherein the one or more performance metrics are determined in dependence on measurements of properties of features formed on the first substrate by the lithographic process.

21. The method according to claim 19, wherein determining the clamping-induced deformation modes comprises:
determining the deformation modes of overall reticle deformation in dependence on the one or more performance metrics;
obtaining data on expected deformation modes of the reticle in a cold state when the reticle is not clamped; and
determining the clamping-induced deformation modes in dependence on the determined deformation modes of the overall reticle deformation and the expected deformation modes of the reticle in a cold state when the reticle is not clamped.

22. The method according to claim 19 wherein the first and second substrates are in different lots of substrates.

23. The method according to claim 19, further comprising performing the method with a reticle in a cold state for each of a plurality of lots of substrates such that, for each lot of substrates, clamping-induced deformation modes of the used reticle are determined;
wherein the applied process corrections to a lithographic process are determined in dependence on the plurality of clamping-induced determinations of deformation modes.

24. A system comprising:
the computer system according to claim 14; and
a lithographic apparatus;
wherein the computer system is configured to control the operation of lithographic apparatus.

25. A device manufacturing method comprising:
using a lithographic process,
the device manufacturing method comprising the method according to claim 19.

26. A non-transitory computer readable medium program comprising computer readable instructions configured to cause a processor to control a lithographic apparatus according to the method of claim 19.
